(19) United States
(12) Patent Application Publication
(10) Pub. No.: US 2026/0113870 A1
(43) Pub. Date: Apr. 23, 2026

(54) METHODS AND APPARATUS TO CONTROL THE TEMPERATURE OF IMMERSION COOLING TANKS

(71) Applicant: Intel Corporation, Santa Clara, CA (US)

(72) Inventors: Brendan T. Pavelek, Beaverton, OR (US); Tanner A. Kantargis, Aloha, OR (US); Jacob Levi McMillian, Beaverton, OR (US); Aravind Munukutla, Hillsboro, OR (US); Samantha Jean Yates, Wilsonville, OR (US)

(73) Assignee: Intel Corporation, Santa Clara, CA (US)

(21) Appl. No.: 19/425,831

(22) Filed: Dec. 18, 2025

(51) Int. Cl. H05K 7/20

(52) U.S. Cl. CPC H05K 7/20236; H05K 7/20272; H05K 7/20281; H05K 7/20772

(57) ABSTRACT

Systems, apparatus, articles of manufacture, and methods to control the temperature of immersion cooling tanks are disclosed. An example apparatus includes a flow control valve to selectively adjust a flow rate of water to be provided to a coolant distribution unit (CDU) associated with an immersion cooling tank. The cooling tank to contain an electronic component immersed in an immersion fluid. The immersion fluid is different from the water. The water is from a source external to the CDU and external to the immersion cooling tank. The example apparatus includes at least one programmable circuit to control operation of the flow control valve.

### BACKGROUND

The use of liquids to cool electronic components is being explored for its benefits over more traditional air cooling systems, as there is an increasing need to address thermal management risks resulting from increased thermal design power in high performance systems (e.g., central processing units (CPUs) and/or graphics processing units (GPUs) in electronic devices such as personal computers and servers). More particularly, relative to air, liquid has inherent advantages of higher specific heat (when no boiling is involved) and higher latent heat of vaporization (when boiling is involved).

### BRIEF DESCRIPTION OF THE DRAWINGS

FIG. 1 is a schematic illustration of an example cooling system constructed in accordance with teachings disclosed herein.

FIG. 2 is an enlarged view of any one of the example water condition adjustment systems coupled to a corresponding CDU and an associated immersion cooling tank.

FIG. 3 is an isometric view of an example water conditions control apparatus that includes an example implementation of the three instances of the water condition adjustment system of FIGS. 1 and 2.

FIG. 4 is an isometric view of the example water conditions control apparatus of FIG. 3 with the frame omitted for purposes of illustration and clarity.

FIG. 5 is an isometric view of the example water conditions control apparatus of FIG. 4 with only one instance of the water condition adjustment system shown for purposes of illustration and further clarity.

FIG. 6 is a sideview of the example instance of the water condition adjustment system shown in FIG. 5.

FIG. 7 is a block diagram of an example implementation of the example water conditions controller circuitry of FIGS. 1-4.

FIG. 8 is a flowchart representative of example machine readable instructions and/or example operations that may be executed, instantiated, and/or performed by example programmable circuitry to implement the water conditions controller circuitry of FIG. 7.

FIG. 9 illustrates an example graphical user interface (GUI) that may be generated by the example GUI generation circuitry of FIG. 7.

FIG. 10 illustrates another example graphical user interface (GUI) that may be generated by the example GUI generation circuitry of FIG. 7.

FIG. 11 illustrates another example graphical user interface (GUI) that may be generated by the example GUI generation circuitry of FIG. 7.

FIG. 12 illustrates another example graphical user interface (GUI) that may be generated by the example GUI generation circuitry of FIG. 7.

FIG. 13 is a block diagram of an example processing platform including programmable circuitry structured to execute, instantiate, and/or perform the example machine readable instructions and/or perform the example operations of FIG. 8 to implement the water conditions controller circuitry of FIG. 7.

FIG. 14 is a block diagram of an example implementation of the programmable circuitry of FIG. 13.

FIG. 15 is a block diagram of another example implementation of the programmable circuitry of FIG. 13.

FIG. 16 is a block diagram of an example software/firmware/instructions distribution platform (e.g., one or more servers) to distribute software, instructions, and/or firmware (e.g., corresponding to the example machine readable instructions of FIG. 8) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale.

### DETAILED DESCRIPTION

Some datacenters employ immersion cooling systems to cool electronic components such as CPUs and/or GPUs present in computing devices such as a server. Immersion cooling systems involve the submersion of electronic components (e.g., servers) directly in an immersion fluid (e.g., coolant, cooling liquid) contained within specialized immersion tanks. To enable the immersion fluid to be in direct contact with the electronic components, the immersion fluid is electrically insulative (e.g., a dielectric liquid). Examples of such dielectric liquids that can be used with examples disclosed herein include dielectric fluid, including hydrocarbons (e.g., mineral oil, hexane, castor oil, etc.), deionized water, silicone oil, artificial coolants (e.g., fluorinated ketones, per-fluorinated compounds, etc.), benzene, liquid noble gases, liquid oxygen, and/or liquid hydrogen.

The immersion fluid within which the electronic components are immersed absorbs heat generated by the electronic components to maintain the components at suitable temperatures while in operation. Typically, immersion tanks are self-contained systems, meaning no immersion fluid leaves the tank in normal use. As a result, additional systems are employed to transfer the heat absorbed by the immersion fluid to the exterior environment. More particularly, heat is often dissipated away from an immersion tank using process chilled water (PCW), which is supplied by an external supply (e.g., in a datacenter) and circulates through a coolant distribution unit (CDU) located within and/or otherwise thermally coupled to the immersion tank. Inside the CDU, a heat exchanger transfers thermal energy from the immersion fluid to the PCW, and the PCW then transports the heat to the external cooling infrastructure (e.g., of a datacenter). The flow rate and/or the temperature of the PCW can vary significantly over time, which can make it difficult to maintain stable immersion fluid temperatures during operation of an electronic component (e.g., a server). Fluctuations in immersion fluid temperature can lead to repeated thermal cycling, which accelerates hardware degradation and shortens the lifespan of the associated electronic component (e.g., a server).

Examples disclosed herein enable dynamic adjustments to the PCW boundary conditions, such as temperature and flow rate, in response to changing facility water conditions, thereby enabling the temperature of an immersion fluid to be maintained and/or controlled to any suitable temperature for consistent thermal performance. Further, in some examples, the system is capable of a “closed-loop heating mode” in which the immersion fluid is to be heated even when one or more electronic components contained in the associated immersion tank are powered down. Such a closed-loop heating mode is useful for preheating the immersion fluid before startup of the electronic component(s), promoting desirable (e.g., optimal) operating conditions from the outset.

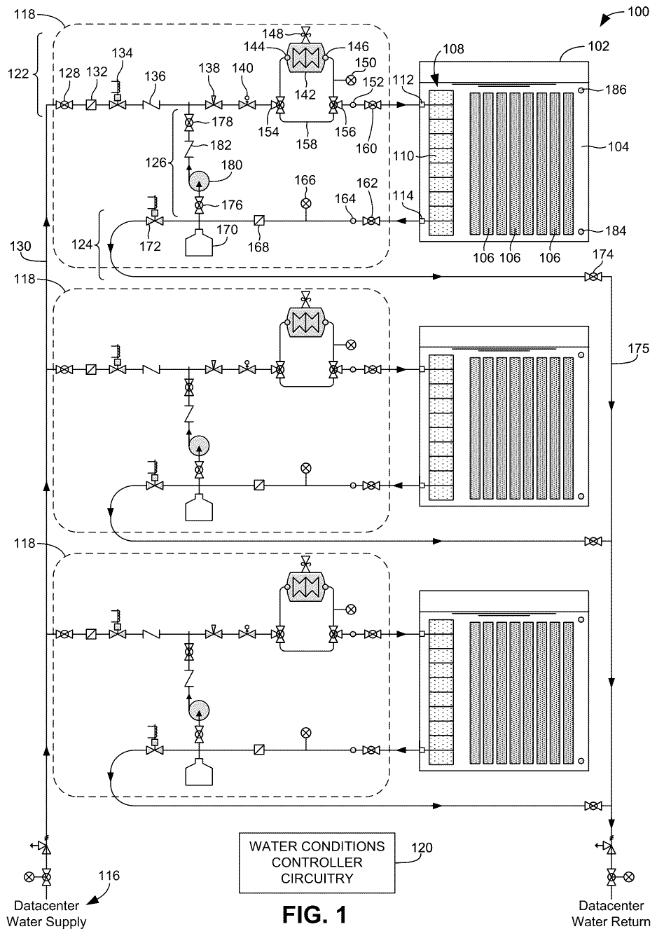

FIG. 1 is a schematic illustration of an example cooling system 100 constructed in accordance with teachings disclosed herein. In this example, the cooling system 100 is implemented at a datacenter. The example cooling system 100 includes three separate immersion cooling tanks 102 that hold an immersion fluid 104 into which one or more electronic components 106 (e.g., servers) are immersed or submerged. In the illustrated example, each of the three cooling tanks 102 are shown to be identical. However, in some examples, the cooling tanks 102 can be different (e.g., different in size, different in volume, manufactured by different manufacturers, hold different number of electronic components, contain different types of the immersion fluid 104, etc.).

The immersion fluid 104 within the cooling tanks 102 serves to draw heat away from the electronic component(s) 106 and then dissipates the heat to a separate fluid (e.g., water) passing through a coolant distribution unit (CDU) 108 operatively coupled to corresponding one of the cooling tanks 102. The CDU 108 can be any suitable type of CDU 108 now known or later developed. For purposes of simplicity, the CDU 108 is represented by a heat exchanger 110 (e.g., a plate heat exchanger) between an inlet 112 and an outlet 114 that are all disposed within the corresponding cooling tank 102. However, in some examples, the CDU 108 can include other components (e.g., sensors, valves, controllers, etc.) that are not shown.

In this example, the separate fluid passing through the CDU 108 is processed water (e.g., facility water) that is provided to the inlet 112 of each CDU 108 from a datacenter water supply 116 to pass through the corresponding heat exchanger 110. In some examples, the water is relatively cold (e.g., processed chilled water (PCW)) to facilitate heat transfer from the heated immersion fluid 104 that is also passed through the heat exchanger 110. As a result, the immersion fluid 104 can continue to draw heat away from the electronic component(s) 106 and dissipate the heat to the water in the CDU 108. Based on this transfer of heat, the water leaves the CDU 108 (e.g., via the outlet 114) at an elevated temperature relative to what the temperature was when entering the CDU 108 at the inlet 112. In some examples, the heated water is then returned to the datacenter water processing facility to be chilled again for reuse. In other examples, the water is not reused as the datacenter water supply provides a continuous stream of fresh processed water.

In the illustrated example, each of the three CDUs 108 are shown to be identical. However, in some examples, the CDUs 108 can differ from one another (e.g., differ in size, design, operation, manufacturer, etc.). Further, in some examples, at least some portion of the CDUs 108 may be external to the cooling tanks 102. In some examples, the CDUs 108 are entirely external to the cooling tank 102 and the immersion fluid 104 is directed out of the tank to the external CDU 108 to enable heat transfer between the immersion fluid 104 and the water passing through the CDU 108.

Datacenters today do not provide significant control of conditions of the processed water delivered to CDUs associated with immersion cooling tanks. That is, while processed water may be chilled to facilitate heat transfer, the precise temperature to which the water is chilled is not controlled to a particular temperature set point. Rather, the temperature of the processed water can vary relatively significantly (e.g., by as much as 3 degrees Celsius (° C) or more). Similarly, the pressure and/or flow rate of the processed water can vary relatively significantly (e.g., by as much as 5 gallons per minute (gpm) or more). What is more, it is not uncommon for changes in upstream operations of the datacenter water processing facility to result in sudden pressure drops in the water that is provided to a CDU. Such variation in temperature, pressure, and/or flow rate of processed water provided to a CDU impact how effectively heat is transferred from the immersion fluid (e.g., liquid coolant) in an immersion cooling tank to the processed water. In the past, techniques to mitigate against the effects of such changes in the conditions of processed water (e.g., changes in temperature, pressure, and/or flow rate of the water) provided to a CDU involve controlling the flow rate at which the immersion fluid is pumped through the heat exchanger of the CDU. Controlling the flow rate of the immersion fluid in response to changing conditions (e.g., changes in temperature, pressure, and/or flow rate) of processed water has been done in the past because it is relatively easy to do so inasmuch as the immersion fluid is within a self-contained system (e.g., a self-contained immersion tank). While controlling the flow rate of the immersion fluid can reduce the impact of unpredictable variations in the processed water, this is a reactionary approach implemented at the point of heat transfer between the immersion fluid and the processed water. As a result, it is difficult to maintain a stable temperature for the immersion fluid using such known techniques.

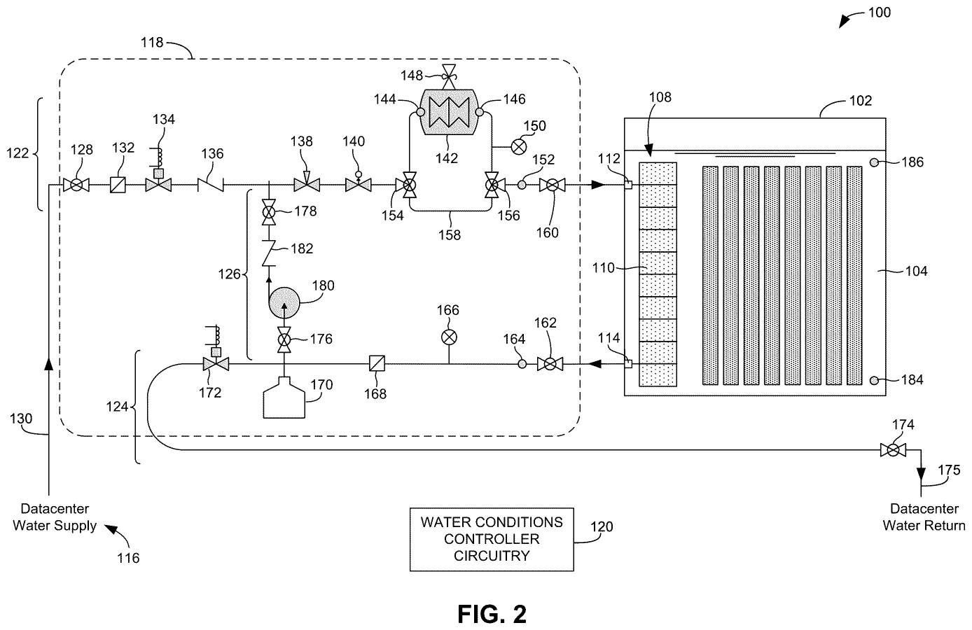

Examples disclosed herein overcome the above challenges of existing cooling system through the implementation of an example water condition adjustment system 118 between the datacenter water supply 116 and an associated CDU 108 and corresponding immersion cooling tank 102. In some examples, a single water condition adjustment system 118 is implemented for multiple CDUs 108 and multiple corresponding cooling tanks 102. However, using a separate water condition adjustment system 118 for each CDU 108 has the advantage of more precise control by responding to the particular circumstances of each CDU 108 based on differences in the temperature of the immersion fluid 104 in the different cooling tanks 102 (e.g., based on differences in the workloads of the electronic components 106 between the different cooling tanks). FIG. 2 is an enlarged view of one of the water condition adjustment systems 118 coupled to a corresponding CDU 108 and an associated immersion cooling tank 102.

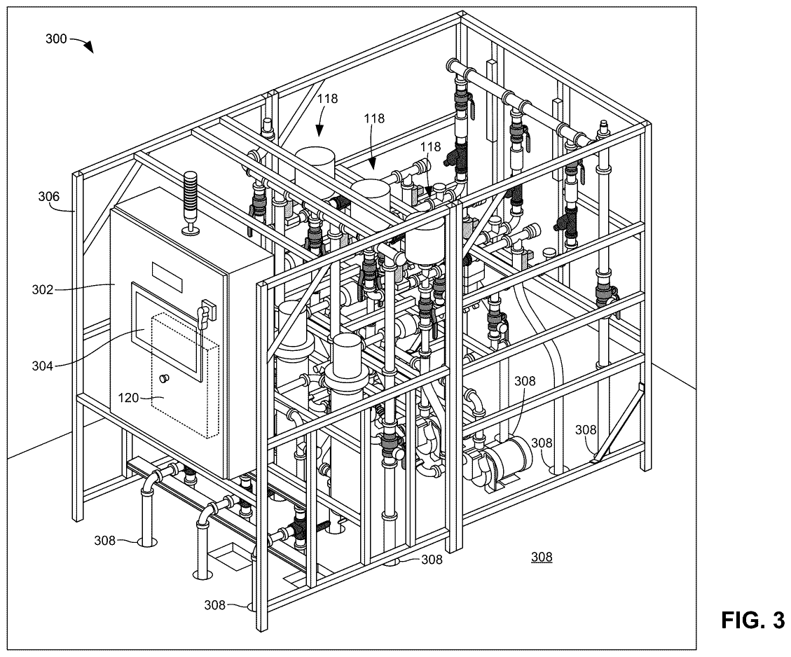

In some examples, although the water condition adjustment systems 118 are independent plumbing systems with distinct components, they are implemented as three parts of a single self-contained apparatus that includes consolidated water conditions controller circuitry 120 (e.g., an example means for controlling operations) to control the operations of the components in each of the water condition adjustment systems 118. More particularly, FIG. 3 is an isometric view of an example water conditions control apparatus 300 that includes the three instances of the water condition adjustment system 118 of FIGS. 1 and 2 as well as a single control box 302 (e.g., housing) for the controller circuitry 120. In this example, the control box 302 includes, carries, and/or supports a display screen 304 to present a graphical user interface generated by the controller circuitry 120. In some examples, the display screen 304 is a touchscreen to enable a user to provide inputs and/or interact with the graphical user interface to direct and/or configure the operations of the controller circuitry 120.

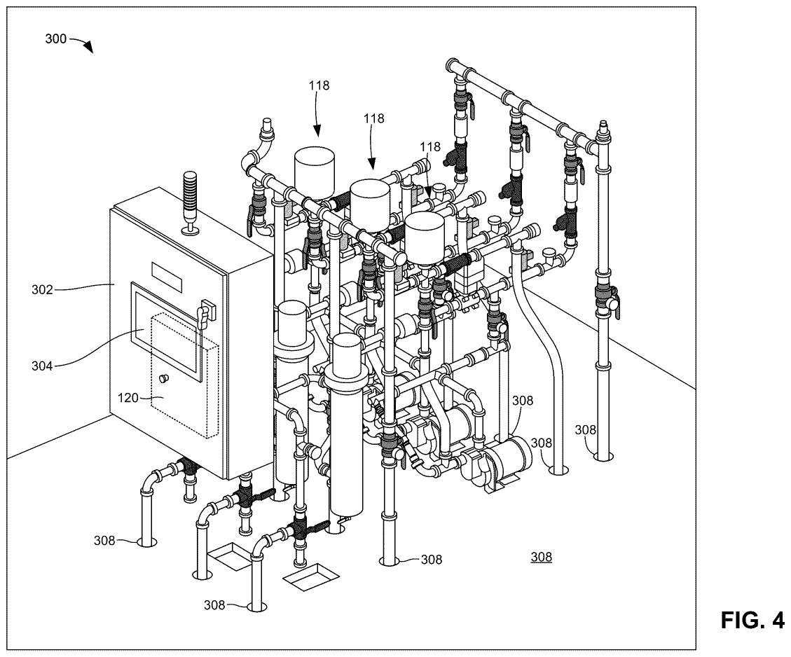

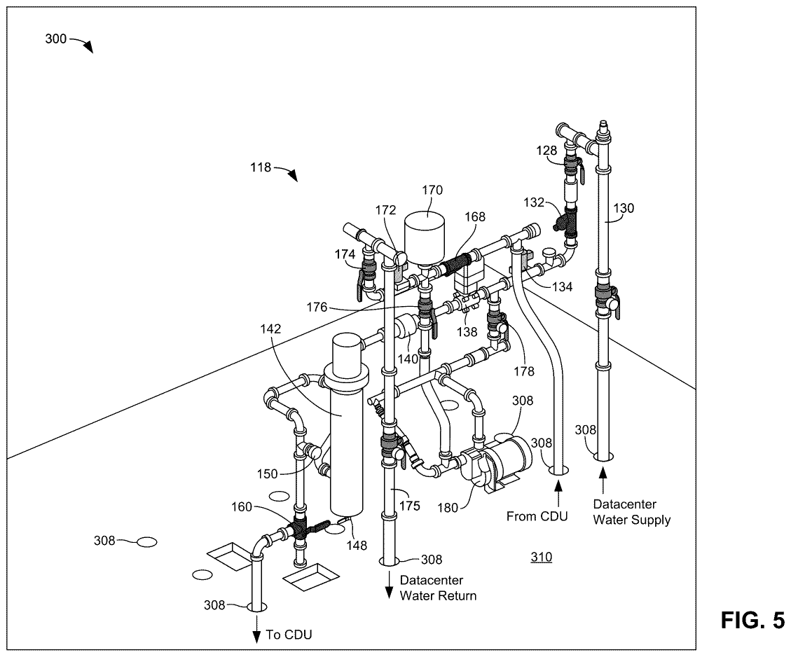

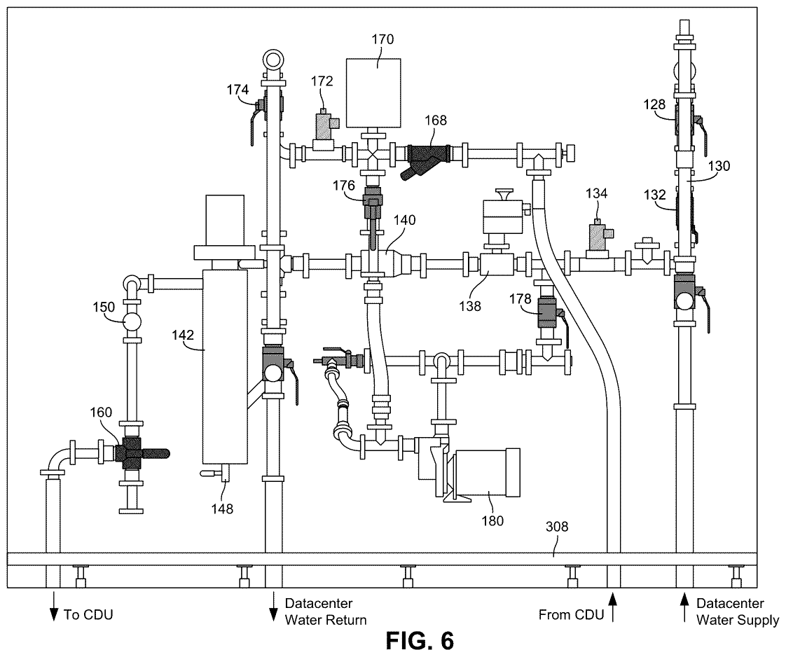

In the illustrated example of FIG. 3, all three water condition adjustment systems 118 and the control box 302 with the controller circuitry 120 are contained within and/or supported by a metal frame 306. FIG. 4 is an isometric view of the example water conditions control apparatus 300 of FIG. 3 with the frame 306 omitted for purposes of illustration and clarity. FIG. 5 is an isometric view of the example water conditions control apparatus 300 of FIG. 4 with only one instance of the water condition adjustment system 118 shown for purposes of illustration and further clarity. For purposes of simplicity and clarity, reference numerals for the different components of the water condition adjustment systems 118 are not provided in FIGS. 3 and 4, but they are provided in FIG. 5. Likewise, for purposes of simplicity and clarity, reference numerals for the corresponding components of the water condition adjustment systems 118 are only provided in the uppermost instance of the water condition adjustment system 118 in FIG. 1. FIG. 6 is a sideview of the example instance of the water condition adjustment system 118 shown in FIG. 5. It should be appreciated that the arrangement of plumbing components shown in FIGS. 3-6 is not identical to the arrangement shown in the schematic diagrams of FIGS. 1-2. Further, many other variations are possible. Additionally, while the example cooling system 100 of FIGS. 1 and 2 and the example water conditions control apparatus 300 of FIGS. 3-6 include three instances of the water condition adjustment system 118, in other examples, any other suitable number (e.g., 1, 2, 4, 5, 6, etc.) of water condition adjustment systems 118 may be implemented.

As shown in the illustrated example of FIGS. 3-6, the example water conditions control apparatus 300 need not be directly adjacent to the immersion cooling tank 102, the CDU 108, and/or the datacenter water supply 116. Rather, the example water conditions control apparatus 300 can be at any suitable location so long as it is in fluid communication with the CDU 108 and the datacenter water supply 116 via appropriate piping and/or plumbing. More particularly, in the illustrated example of FIGS. 3-6, the example water conditions control apparatus 300 is fluidly coupled to the CDU 108 through piping that extends under the floor 310 after passing through openings 308 in the floor 310. In other examples, the piping is provided above the floor 310.

Turning in detail to a discussion of the example water condition adjustment systems 118 of FIGS. 1-6, each system includes an inlet pipeline 122 (e.g., supply pipeline), an outlet pipeline 124 (e.g., return pipeline), and a closed loop pipeline 126. All three of the pipelines 122, 124, 126 are example means for fluidly coupling different parts of the example water condition adjustment system 118. As shown, the example inlet pipeline 122 provides a flow path for the water from the datacenter water supply 116 to the inlet 112 of the CDU 108. The example outlet pipeline 124 is coupled to the outlet 114 of the CDU 108 and provides a return path for the water. The example closed loop pipeline 126 provides a flow path for the water between the outlet pipeline 124 and the inlet pipeline 122 that is independent of the CDU 108 and independent of the datacenter water supply 116.

As shown in the illustrated example, the upstream end of the inlet pipeline 122 includes a first valve 128 associated with an inlet of the example water condition adjustment system 118. That is, the first valve 128 is coupled to a distribution manifold 130 that delivers water from the datacenter water supply 116 to each of the water condition adjustment systems 118. In some examples, there are no flow balancing components in the distribution manifold because any differences in flow delivered to each of the different water condition adjustment systems 118 can be corrected by the flow control techniques disclosed herein that are implemented in each instance of the system 118. In some examples, the first valve 128 is a manual ball valve. However, in other examples, a different type of valve may be used (e.g., a control valve that can be automatically controlled). In some examples, the first valve 128 may be omitted.

The example inlet pipeline 122 includes an example first Y-strainer 132. In some examples, the first Y-strainer 132 is omitted.

Moving further downstream, the example inlet pipeline 122 includes a first example solenoid valve 134 that may be controlled by the controller circuitry 120. In this example, the solenoid valve 134 is normally open (e.g., open in a default state). In some examples, the first solenoid valve 134 is closed when the water condition adjustment system 118 is to operate in a closed loop mode as discussed further below. In some examples, when there is no need to implement the closed loop mode, the first solenoid valve 134 may be omitted. In some examples, a different type of valve (e.g., a manually operated valve) may be used instead of a solenoid valve.

In the illustrated example, the inlet pipeline 122 includes a first check valve 136 to permit fluid flow downstream the pipeline towards the CDU 108 while preventing fluid flow in the opposite direction. In some examples, the first check valve 136 is omitted.

The inlet pipeline 122 of the FIGS. 1-6 next includes an example flow control valve 138 (e.g., an example means for adjusting a flow rate). In some examples, the flow control valve 138 is a v-port flow control valve to enable precise control of fluid flow through the valve. However, in other examples, other types of flow control valves may be used. In some examples, the flow control valve 138 is controlled by the controller circuitry 120 to adjust the flow rate of processed water provided to the CDU 108. In this manner, variations in pressure and/or flow rate of the processed water from the datacenter water supply 116 can be smoothed out and/or mitigated against before the water reaches the CDU 108. In some examples, the controller circuitry 120 controls the flow control valve 138 based on feedback from a flowmeter 140 (e.g., an example means for measuring a flow rate) that is just downstream of the flow control valve. More particularly, in some examples, the flowmeter 140 provides a measured flow rate to the controller circuitry 120 that is compared against a target flow rate (e.g., a flow rate setpoint). The controller circuitry 120 adjusts the opening of the flow control valve based on differences between the measured and target flow rates in substantially real time. In some examples, the controller circuitry 120 is a programmable logic controller (PLC) that implements a proportional-integral-derivative (PID) feedback loop to control the flow rate of the processed water. In some examples, the flowmeter 140 is a magnetic inductance flowmeter. In other examples, different types of flowmeters may be employed. In some examples, the flowmeter 140 can be at a different location along the inlet pipeline 122 relative to the flow control valve 138 (e.g., further downstream closer to the CDU 108 with one or more other components therebetween). In some examples, where controlling the flow rate is not needed (e.g., when temperature is to be the focus of the water condition adjustment system 118), the flow control valve 138 and/or the flowmeter 140 may be omitted.

In the illustrated example, the inlet pipeline 122 includes an example heater 142 (e.g., an example means for heating) that can be activated by the controller circuitry 120 to heat the processed water passing therethrough before the water reaches the CDU 108. Although the heater 142 is downstream of the flowmeter 140 in the illustrated example, in other examples, the heater 142 can be upstream from the flow control valve 138 and/or the flowmeter 140. In some examples, the heater 142 is associated with first temperature sensor 144 (e.g., a limit thermocouple) at an inlet to the heater 142 and a second temperature sensor 146 (e.g., a process thermocouple) at an outlet of the heater 142. In some examples, the first temperature sensor 144 monitors or measures a temperature of the water entering the heater 142 and the second temperature sensor 146 measures the temperature of the water leaving the heater 142. In some examples, one or both of the temperature sensors 144, 146 are omitted. In some examples, the heater 142 includes and/or is associated with a pressure relief valve 148. In other examples, the pressure relief valve 148 is omitted. In some examples, a first pressure gauge 150 is provided downstream of the heater 142 to measure the pressure of the water within the inlet pipeline 122. In other examples, the first pressure gauge 150 is omitted.

In some examples, the controller circuitry 120 controls the activation of the heater 142 based on feedback from either of the temperature sensors 144, 146 associated with the heater 142 and/or based on feedback from a third temperature sensor 152 (e.g., a resistance temperature detector (RTD)) that is closer to the inlet 112 of the CDU 108. More particularly, in some examples, one or more of the temperature sensors 144, 146, 152 provide measured temperature(s) to the controller circuitry 120 that are compared against a target temperature (e.g., a temperature setpoint). The controller circuitry 120 adjusts the power provided to the heater 142 based on differences between the measured and target temperatures in substantially real time. In some examples, the controller circuitry 120 toggles the heater between ON and OFF power states in a controlled manner (e.g., via pulse width modulation) to control the heating of the water passing through the heater 142.

In some examples, the heater 142 is positioned between first and second diverter valves 154, 156 in parallel with a bypass pipeline 158 (e.g., example means for bypassing) that also extends between the diverter valves 154, 156. The bypass pipeline 158 and the associated diverter valves 154, 156 enable the processed water in the inlet pipeline 122 to bypass the heater 142. In some examples, the bypass pipeline 158 and the associated diverter valves 154, 156 are omitted. In some examples, where heating the water is not expected to be needed (e.g., when the flow rate is to be the focus of the water condition adjustment system 118), the heater 146 and associated components may be omitted entirely rather than merely bypassed.

In this example, the downstream end of the inlet pipeline 122 includes a second valve 160 that is proximate and coupled to the inlet 112 of the CDU 108. In some examples, the second valve 160 is a manual ball valve. However, in other examples, a different type of valve may be used (e.g., a control valve that can be automatically controlled). In some examples, the second valve 160 is omitted.

In the illustrated example of FIGS. 1-6, the upstream end of the outlet pipeline 124 includes a third valve 162 that is proximate and coupled to the outlet 114 of the CDU 108. In some examples, the third valve 162 is a manual ball valve. However, in other examples, a different type of valve may be used (e.g., a control valve that can be automatically controlled). In some examples, the third valve 162 is omitted.

The example outlet pipeline 124 of the FIGS. 1-6 next includes a fourth temperature sensor 164 (e.g., an RTD) to measure the temperature of the water after exiting the CDU 108 (e.g., after drawing heat away from the immersion fluid 104). In some examples, the controller circuitry 120 uses the temperature measured by the fourth temperature sensor 164 in addition to or instead of the temperatures measured by the first, second, and/or third temperature sensors 144, 146, 152. In some examples, the fourth temperature sensor 164 is omitted.

In some examples, the outlet pipeline 124 includes a second pressure gauge 166 downstream of the fourth temperature sensor 164 to measure the pressure of the water within the outlet pipeline 124. In other examples, the second pressure gauge 166 is omitted.

The example outlet pipeline 124 includes an example second Y-strainer 168. In some examples, the second Y-strainer 168 is omitted.

In the illustrated example of FIGS. 1-6, the outlet pipeline 124 includes an example expansion tank 170. In this example, the expansion tank is proximate the closed loop pipeline 126. However, in other examples, the expansion tank 170 can be at any other suitable location. In some examples, the expansion tank 170 is coupled to the inlet pipeline 122 (e.g., adjacent the heater 142). In some examples, the expansion tank 170 is omitted.

Moving further downstream, the example outlet pipeline 124 includes a second example solenoid valve 172 that may be controlled by the controller circuitry 120. In this example, the second solenoid valve 172 is normally open (e.g., open in a default state). In some examples, the second solenoid valve 172 is closed when the water condition adjustment system 118 is to operate in a closed loop mode as discussed further below. In some examples, when there is no need to implement the closed loop mode, the second solenoid valve 172 may be omitted. In some examples, a different type of valve (e.g., a manually operated valve) may be used instead of a solenoid valve. Both of the solenoid valves 134, 172 are example means for closing off the water from a water processing facility of the associated datacenter.

In some examples, the downstream end of the outlet pipeline 124 includes a fourth valve 174 (shown outside the dashed box demarcating the water condition adjustment system 118 in FIGS. 1 and 2). In this example, the fourth valve 174 is coupled to a return manifold 175 that delivers the processed water back to the datacenter water processing facility. In some examples, the fourth valve 174 is a manual ball valve. However, in other examples, a different type of valve may be used (e.g., a control valve that can be automatically controlled). In some examples, the fourth valve 174 is omitted.

In the illustrated example of FIGS. 1-6, first and second opposing ends of the closed loop pipeline 126 include respective fifth and sixth valves 176, 178. The fifth and sixth valves 176, 178 enable the closed loop pipeline 126 to be either closed off to the inlet and outlet pipelines 122, 124 or to provide a path that leads directly from the outlet pipeline 124 back to the inlet pipeline 122. More particularly, in this example, the closed loop pipeline 126 begins just upstream of the second solenoid valve 172 on the outlet pipeline 124 and ends just downstream of the first solenoid valve 134. Accordingly, when the first and second solenoid valves 134, 172 are closed and the fifth and sixth valves 176, 178 are open, the closed loop pipeline 126 defines a closed loop in combination with the inlet pipeline 122, the outlet pipeline 124, and the CDU 108. In some examples, the closed loop pipeline 126 includes a pump 180 (e.g., an example means for pumping) to pump the water within the closed loop around the loop. In some examples, the closed loop pipeline 126 includes a second check valve 182 to permit fluid flow around the closed loop in the direction forced by the pump 180 while preventing fluid flow in the opposite direction. In some examples, the second check valve 182 is omitted. In some examples, one or more other components on the closed loop pipeline 126 and/or the entire closed loop pipeline 126 is omitted.

As discussed above, in some examples, the controller circuitry 120 controls operation of the components within the water condition adjustment system 118. Thus, in some examples, the controller circuitry 120 is in communication with different ones of the components including both sensors that provide feedback to the controller circuitry 120 and actuators or other active components that operate based on signals and/or commands from the controller circuitry 120. More particularly, in the illustrated example of FIGS. 1 and 2, the components that are in communication with and/or automatically controlled by the controller circuitry 120 are shaded, whereas the components that do not communicate with the controller circuitry 120 are not shaded. Thus, in this example, the controller circuitry 120 is in communication with the first and second solenoid valves 134, 172, the flow control valve 138, the flowmeter 140, the heater 142, the first, second, third, and fourth temperature sensors 144, 146, 152, 164, and the pump 180. Communications between the controller circuitry 120 and the above-noted components can be via a wired and/or wireless connection. In some examples, one or more of the aforementioned components is not communicatively coupled to and/or controlled by the controller circuitry 120. Further, in some examples, additional components within the water condition adjustment system 118 are in communication with and/or controlled by the controller circuitry 120. Additionally, in some examples, the controller circuitry 120 may be in communication with other components that are not part of the water condition adjustment system 118. For instance, in some examples, the circuitry 120 is in communication with and receives feedback from the one or more temperature sensors (e.g., a bottom temperature sensor 184 and a top temperature sensor 186) within the immersion cooling tank 102 to measure the temperature of the immersion fluid 104. Accordingly, in some examples, the controller circuitry 120 may control the flow control valve 138 and/or the heater 142 based on the measured temperature of the immersion fluid 104 in addition to or instead of the other sensor data discussed above. In this example, the bottom and top temperature sensors 184, 186 within the tank 102 are resistance temperature detectors (RTDs). In some examples, one or both of the bottom and top temperature sensors 184, 186 may be omitted. Any of the example temperatures 144, 146, 152, 164, 184, 186 are an example means for measuring a temperature.

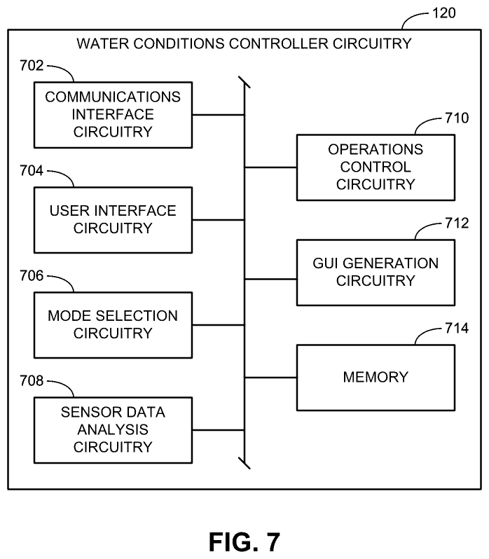

FIG. 7 is a block diagram of an example implementation of the water conditions controller circuitry 120 of FIGS. 1-4 to do control the boundary conditions (e.g., temperature, pressure, flow rate, etc.) of processed water supplied to a CDU associated with an immersion cooling tank (e.g., any of the CDUs 108 associated with corresponding ones of the cooling tanks 102 of FIGS. 1 and 2). The water conditions controller circuitry 120 of FIG. 7 may be instantiated (e.g., creating an instance of, bring into being for any length of time, materialize, implement, etc.) by programmable circuitry. For example, programmable circuitry may be implemented by a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Additionally or alternatively, the water conditions controller circuitry 120 of FIG. 7 may be instantiated (e.g., creating an instance of, bring into being for any length of time, materialize, implement, etc.) by (i) an Application Specific Integrated Circuit (ASIC) and/or (ii) a Field Programmable Gate Array (FPGA) (e.g., another form of programmable circuitry) structured and/or configured in response to execution of second instructions to perform operations corresponding to the first instructions. It should be understood that some or all of the circuitry of FIG. 7 may, thus, be instantiated at the same or different times. Some or all of the circuitry of FIG. 7 may be instantiated, for example, in one or more threads executing concurrently on hardware and/or in series on hardware. Moreover, in some examples, some or all of the circuitry of FIG. 7 may be implemented by microprocessor circuitry executing instructions and/or FPGA circuitry performing operations to implement one or more virtual machines and/or containers.

As illustrated in FIG. 7, the example water conditions controller circuitry 120 includes example communications interface circuitry 702, example user interface circuitry 704, example mode selection circuitry 706, example sensor data analysis circuitry 708, example operations control circuitry 710, example graphical user interface (GUI) generation circuitry 712, and example memory 714.

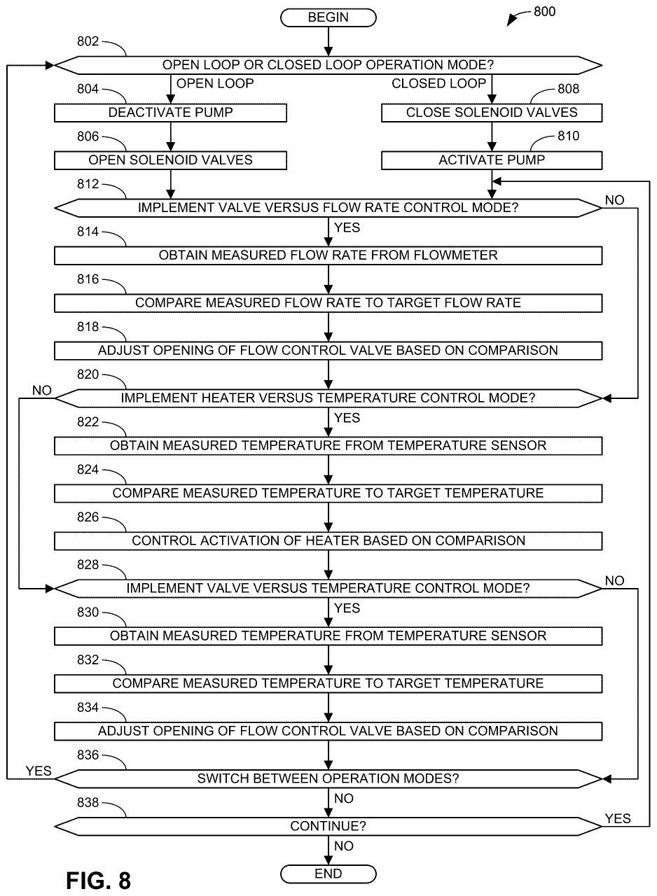

In the illustrated example, the water conditions controller circuitry 120 is provided with the example communications interface circuitry 702 to enable communications with the components associated with the water condition adjustment systems 118 of FIGS. 1-6. That is, in some examples, the communications interface circuitry 702 enables the water conditions controller circuitry 120 to receive feedback from sensor devices such as the flowmeter 140 and/or the temperature sensors 144, 146, 152, 164. Additionally, the example communications interface circuitry 702 enables the water conditions controller circuitry 120 to send signals and/or commands directing the operation of the control components such as the solenoid valves 134, 172, the flow control valve 138, the heater 142, and/or the pump 180. In some examples, the communication circuitry 702 is to receive signals back from such control components. In some examples, the communications interface circuitry 702 also communicates with components associated with the cooling tank 102 and/or the CDU 108 such as the temperature sensors 184, 186 within the cooling tank 102. In some examples, the same communications interface circuitry 702 communicates with more than one (e.g., all) instances of the water condition adjustment systems 118 (e.g., three in the illustrated example of FIGS. 1-6). In other examples, multiple instances of the communication circuitry 702 may be implemented to independently communicate with different ones of the water condition adjustment systems 118. In some examples, the communications interface circuitry 702 is instantiated by programmable circuitry executing communications instructions and/or configured to perform operations such as those represented by the flowchart of FIG. 8.

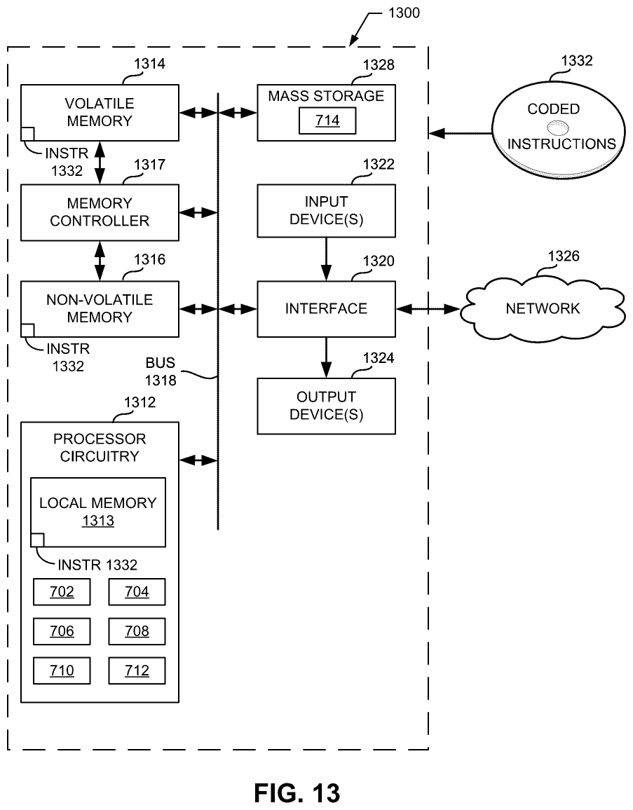

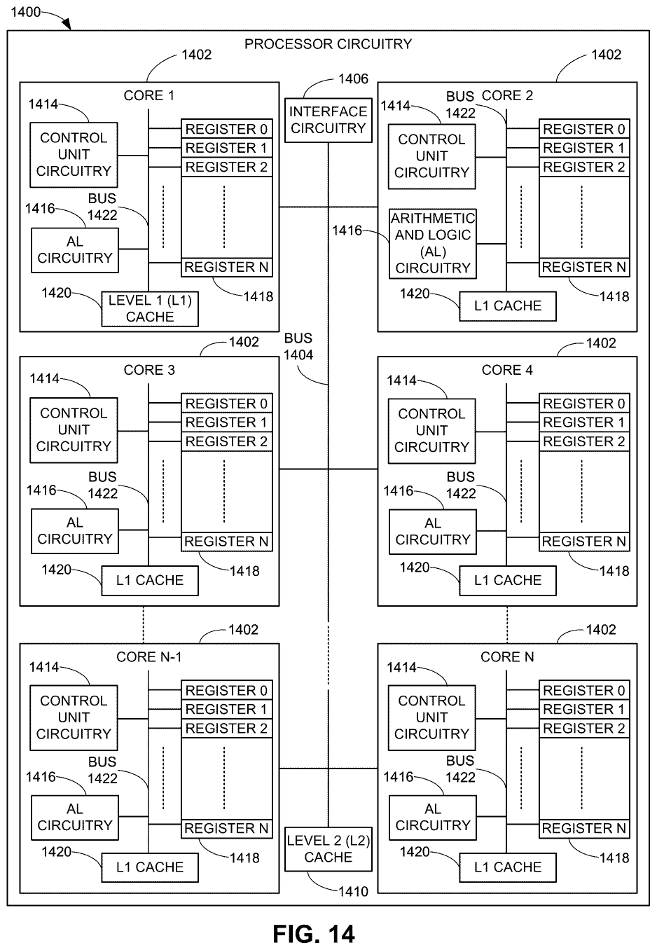

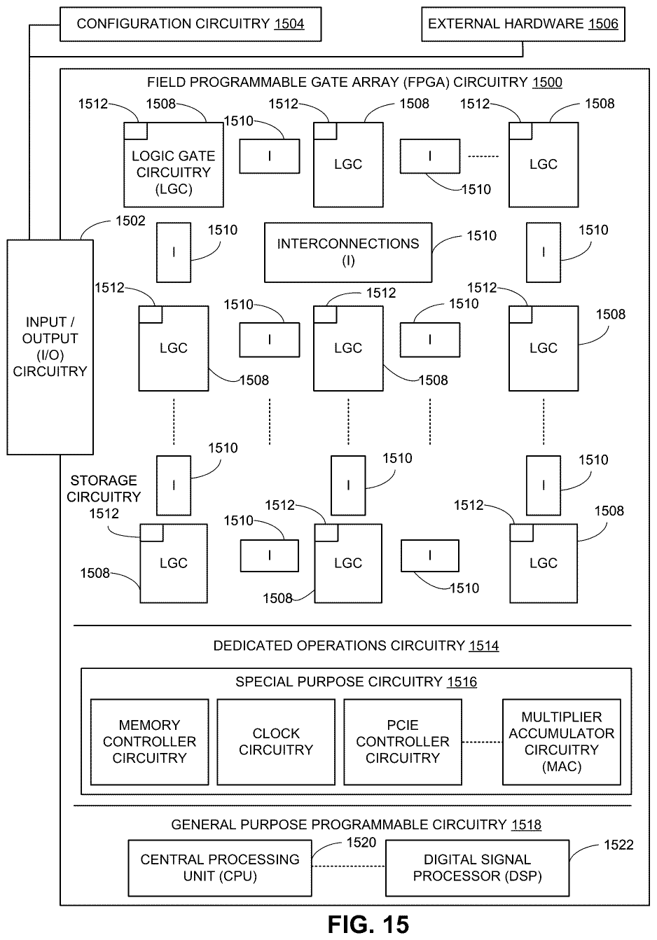

In some examples, the water conditions controller circuitry 120 includes means for communicating. For example, the means for communicating may be implemented by communications interface circuitry 702. In some examples, the communications interface circuitry 702 may be instantiated by programmable circuitry such as the example programmable circuitry 1312 of FIG. 13. For instance, the communications interface circuitry 702 may be instantiated by the example microprocessor 1400 of FIG. 14 executing machine executable instructions such as those implemented by at least blocks 814, 822, and 830 of FIG. 8. In some examples, the communications interface circuitry 702 may be instantiated by hardware logic circuitry, which may be implemented by an ASIC, XPU, or the FPGA circuitry 1500 of FIG. 15 configured and/or structured to perform operations corresponding to the machine readable instructions. Additionally or alternatively, the communications interface circuitry 702 may be instantiated by any other combination of hardware, software, and/or firmware. For example, the communications interface circuitry 702 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In the illustrated example, the water conditions controller circuitry 120 is provided with the example user interface circuitry 704 to receive user inputs for configuring and/or controlling the operations of the water conditions controller circuitry 120. For instance, in some examples, the user interface circuitry 704 receives input from a user defining setpoints or target values for process parameters to be controlled by the water conditions controller circuitry 120. In some examples, such setpoints or target values are stored in the example memory 714. Further, in some examples, the user interface circuitry 704 receives inputs from a user selecting a particular operation mode and/or control mode for the example water conditions adjustment system 118. In some examples, the user interface circuitry 704 receives input from a user confirming manual actions (e.g., manually closing and/or manually opening valves) have been completed that are associated with particular operation modes and/or control modes. User inputs received by the user interface circuitry 704 can be obtained using any suitable human machine interface (e.g., discrete buttons, a keyboard, a touchscreen, etc.). In some examples, the user interface circuitry 704 is instantiated by programmable circuitry executing user interface instructions and/or configured to perform operations such as those represented by the flowchart of FIG. 8.

In some examples, the water conditions controller circuitry 120 includes means for interfacing with a user. For example, the means for interfacing may be implemented by user interface circuitry 704. In some examples, the user interface circuitry 704 may be instantiated by programmable circuitry such as the example programmable circuitry 1312 of FIG. 13. For instance, the user interface circuitry 704 may be instantiated by the example microprocessor 1400 of FIG. 14 executing machine executable instructions such as those implemented by at least blocks 810, 812, 820, and 828 of FIG. 8. In some examples, the user interface circuitry 704 may be instantiated by hardware logic circuitry, which may be implemented by an ASIC, XPU, or the FPGA circuitry 1500 of FIG. 15 configured and/or structured to perform operations corresponding to the machine readable instructions. Additionally or alternatively, the user interface circuitry 704 may be instantiated by any other combination of hardware, software, and/or firmware. For example, the user interface circuitry 704 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In the illustrated example, the water conditions controller circuitry 120 is provided with the example mode selection circuitry 706 to facilitate the selection of different operation modes. In some examples, the different operation modes include (1) an open loop mode, and (2) a closed loop mode. In the open loop operation mode, water passing through the inlet pipeline 122 of the example water condition adjustment systems 118 remains separated from and independent of the water passing through the outlet pipeline 124. That is, in the open loop operation mode, water from the datacenter water supply 116 passes through the inlet pipeline 122 to the CDU 108 and then, once it leaves the CDU 108, the water passes through the outlet pipeline 124 to return to the water processing facility of the datacenter without further direct interaction with the inlet pipeline 122. By contrast, in the closed loop operation mode, water in the outlet pipeline 124 is directly returned to the inlet pipeline 122 (by way of the closed loop pipeline 126) to be routed back through the CDU 108. In some example implementations of the closed loop operation mode, both the inlet and outlet pipelines 122, 124 are closed off from the water processing facility of the datacenter. As a result, the closed loop operation mode involves a fixed volume of water that is retained within and cycled through a closed loop defined by the inlet pipeline 122, the CDU 108, the outlet pipeline 124, and the closed loop pipeline 126.

The open loop operation mode is useful under normal operations when the electronic component(s) 106 (e.g., servers) within the cooling tank 102 are operating and producing heat that needs to be dissipated. The closed loop operation mode is useful in situations where there is a low heat load produced from the electronic component(s) 106 within the cooling tank 102 (or no heat because the component(s) 106 are powered down) and a relatively high bath temperature is desired. In this context, a relatively high bath temperature is a temperature of the immersion fluid 104 that is higher than what would result by relying exclusively on the heat (if any) generated from the electronic component(s) 106. An example scenario when the closed loop operation mode may be used is before server startup when it is desired to preheat the immersion fluid 104 within the cooling tank 102 to a particular (e.g., optimal) temperature to be used once the electronic component(s) 106 are powered on and begin operating. In some examples, the heater 142 can continuously add energy to the water in the closed loop mode to increase the water temperature to as much as 70° C. (depending on insulation in the plumbing). In some examples, the mode selection circuitry 706 determines which operation mode to use based on user input (e.g., provided via the user interface circuitry 704).

In some examples, when the operation mode is to be switched from one mode to the other, the mode selection circuitry 706 prompts a user to manually adjust the fifth and sixth valves 176, 178 at either end of the closed loop pipeline 126 before implementing the user selected mode. More particularly, in some examples, the mode selection circuitry 706 prompts the user to open the fifth and sixth valves 176, 178 for the closed loop operation mode and to close the valves for the open loop operation mode. In some examples, the mode selection circuitry 706 obtains confirmation that the fifth and sixth valves 176, 178 are properly adjusted before switching to the selected operation mode. In some examples, confirmation of such is obtained by user input (e.g., via the user interface circuitry 704). In other examples, such confirmation is obtained from sensors associated with the fifth and sixth valves 176, 178. In some examples, the fifth and sixth valves 176, 178 are automatically controlled without the need for a user to manually adjust the valves.

In addition to determining the operation mode, in some examples, the mode selection circuitry 706 also determines the control mode(s) to be implemented by the water conditions controller circuitry 120. In some examples, different control modes that the water conditions controller circuitry 120 may implement include (1) a valve versus flow rate control mode, (2) a heater versus temperature control mode, and (3) a valve versus temperature control mode. In the valve versus flow rate control mode, the extent (e.g., percentage) that the flow control valve 138 is open (between fully closed and fully open) is controlled and/or adjusted to reach a desired reading on the flowmeter 140 (e.g., a setpoint or target flow rate). In the heater versus temperature control mode, activation of the heater 142 is controlled and/or adjusted (e.g., power is applied to the heater 142 via pulse width modulation) to reach a desired reading on a user-selectable temperature setpoint (e.g., a target temperature at the location of any of the temperature sensors 144, 146, 152, 164, 184, 186). In the valve versus temperature control mode, the extent (e.g., percentage) that the flow control valve 138 is open (between fully closed and fully open) is controlled and/or adjusted to reach a desired temperature reading from any of the temperature sensors 184, 186 in the cooling tank 102 (e.g., a setpoint or target temperature).

Any of the foregoing example control modes can be implemented individually. In some examples, both the valve versus flow rate control mode and the heater versus temperature control mode are implemented concurrently. However, inasmuch as the valve versus temperature control mode uses a temperature input to control a valve that affects flow rate, the valve versus temperature control mode is mutually exclusive to the other two. Accordingly, in some examples, when this third control mode is selected, the example mode selection circuitry 706 deselects the other two control modes.

In some examples, the mode selection circuitry 706 is instantiated by programmable circuitry executing mode selection instructions and/or configured to perform operations such as those represented by the flowchart of FIG. 8.

In some examples, the water conditions controller circuitry 120 includes means for determining at least one of an operation mode or a control mode for the water conditions controller circuitry 120. For example, the means for determining may be implemented by mode selection circuitry 706. In some examples, the mode selection circuitry 706 may be instantiated by programmable circuitry such as the example programmable circuitry 1312 of FIG. 13. For instance, the mode selection circuitry 706 may be instantiated by the example microprocessor 1400 of FIG. 14 executing machine executable instructions such as those implemented by at least blocks 802, 812, 820, 828, and 836 of FIG. 8. In some examples, the mode selection circuitry 706 may be instantiated by hardware logic circuitry, which may be implemented by an ASIC, XPU, or the FPGA circuitry 1500 of FIG. 15 configured and/or structured to perform operations corresponding to the machine readable instructions. Additionally or alternatively, the mode selection circuitry 706 may be instantiated by any other combination of hardware, software, and/or firmware. For example, the mode selection circuitry 706 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In the illustrated example, the water conditions controller circuitry 120 is provided with the example sensor data analysis circuitry 708 to analyze the data received from the sensors via the communications interface circuitry 702. In some examples, the sensor data analysis circuitry 708 directs the communication interface circuitry 702 to request sensor data (e.g., feedback data) from sensors (e.g., the flowmeter 140 and/or the temperature sensors 144, 146, 152, 164, 184, 186). In other examples, the sensors are configured to automatically provide sensor data (e.g., measure flow rates, measured temperatures, etc.) to the water conditions controller circuitry 120 via the communication interface circuitry 702. In some such examples, the sensor data analysis circuitry 708 analyzes the sensor data as it is received. In other examples, as sensor data is received from the sensors, the data is stored in the example memory 714 and the example sensor data analysis circuitry 708 retrieves the sensor data from the memory 714 when needed for analysis. Regardless of how the sensor data is obtained, the example sensor data analysis circuitry 708 compares the measured values to corresponding setpoints or target values to determine how the flow control valve 138 and/or the heater 142 are to be adjusted. In some examples, the sensor data analysis circuitry 708 compares the measured values to target values to implement a proportional-integral-derivate (PID) feedback loop. In some examples, the sensor data analysis circuitry 708 is instantiated by programmable circuitry executing sensor data analysis instructions and/or configured to perform operations such as those represented by the flowchart of FIG. 8.

In some examples, the water conditions controller circuitry 120 includes means for determining adjustments to be made to flow control valve 138 and/or the heater 142. For example, the means for determining may be implemented by sensor data analysis circuitry 708. In some examples, the sensor data analysis circuitry 708 may be instantiated by programmable circuitry such as the example programmable circuitry 1312 of FIG. 13. For instance, the sensor data analysis circuitry 708 may be instantiated by the example microprocessor 1400 of FIG. 14 executing machine executable instructions such as those implemented by at least blocks 814, 816, 822, 824, 830, and 832 of FIG. 8. In some examples, the sensor data analysis circuitry 708 may be instantiated by hardware logic circuitry, which may be implemented by an ASIC, XPU, or the FPGA circuitry 1500 of FIG. 15 configured and/or structured to perform operations corresponding to the machine readable instructions. Additionally or alternatively, the sensor data analysis circuitry 708 may be instantiated by any other combination of hardware, software, and/or firmware. For example, the sensor data analysis circuitry 708 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In the illustrated example, the water conditions controller circuitry 120 is provided with the example operations control circuitry 710 to control operation of the flow control valve 138, the heater 142, the solenoid valves 134, 172, and/or the pump 180. More particularly, in some examples, the operations control circuitry 710 generates signals and/or commands to cause adjustments to the extent (e.g., percentage) that the flow control valve 138 is open based on the determination of the sensor data analysis circuitry 708. Similarly, in some examples, the operations control circuitry 710 generates signals and/or commands to cause the heater 142 to be activated (e.g., turned on to heat up) based on the determination of the sensor data analysis circuitry 708 indicating such is needed to reach the target temperature. Further, in some examples, the operations control circuitry 710 generates signals and/or commands to open the solenoid valves 134, 172 (e.g., when switching to the closed loop operation mode) or to open the solenoid valves 134, 172 (e.g., when switching to the open loop operation mode). As described above, in some examples, the solenoid valves 134, 172 are normally open (e.g., open in a default state). As such, no signal needs to be provided if the solenoid valves 134, 172 are to be open. In some examples, the operations control circuitry 710 generates signals and/or commands to activate and/or control the pump 180 based on the operation mode as determined by the example mode selection circuitry 706. In some examples, the signals and/or commands generated by the operations control circuitry 710 are transmitted to the flow control valve 138, the heater 142, the solenoid valves 134, 172, and/or the pump 180 via the example communications interface circuitry 702. In some examples, the operations control circuitry 710 is instantiated by programmable circuitry executing operations control instructions and/or configured to perform operations such as those represented by the flowchart of FIG. 8.

In some examples, the water conditions controller circuitry 120 includes means for controlling operations of the flow control valve 138, the heater 142, the solenoid valves 134, 172, and/or the pump 180. For example, the means for controlling may be implemented by operations control circuitry 710. In some examples, the operations control circuitry 710 may be instantiated by programmable circuitry such as the example programmable circuitry 1312 of FIG. 13. For instance, the operations control circuitry 710 may be instantiated by the example microprocessor 1400 of FIG. 14 executing machine executable instructions such as those implemented by at least blocks 804, 806, 808, 810, 818, 826, 834, and 838 of FIG. 8. In some examples, the operations control circuitry 710 may be instantiated by hardware logic circuitry, which may be implemented by an ASIC, XPU, or the FPGA circuitry 1500 of FIG. 15 configured and/or structured to perform operations corresponding to the machine readable instructions. Additionally or alternatively, the operations control circuitry 710 may be instantiated by any other combination of hardware, software, and/or firmware. For example, the operations control circuitry 710 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In the illustrated example, the water conditions controller circuitry 120 is provided with the example GUI generation circuitry 712 to generate a GUI that can be presented to a user to represent the status of the water condition adjustment systems 118, its associated components, and/or the conditions of the processed water passing through the water condition adjustment systems 118. In some examples, the generated GUI provides prompts and/or facilitates a user to provide inputs to configure the system. In some examples, the GUI generation circuitry 712 is instantiated by programmable circuitry executing GUI generation instructions and/or configured to perform operations such as those represented by the flowchart of FIG. 8.

In some examples, the water conditions controller circuitry 120 includes means for generating a graphical user interface. For example, the means for generating may be implemented by GUI generation circuitry 712. In some examples, the GUI generation circuitry 712 may be instantiated by programmable circuitry such as the example programmable circuitry 1312 of FIG. 13. For instance, the GUI generation circuitry 712 may be instantiated by the example microprocessor 1400 of FIG. 14 executing machine executable instructions. In some examples, the GUI generation circuitry 712 may be instantiated by hardware logic circuitry, which may be implemented by an ASIC, XPU, or the FPGA circuitry 1500 of FIG. 15 configured and/or structured to perform operations corresponding to the machine readable instructions. Additionally or alternatively, the GUI generation circuitry 712 may be instantiated by any other combination of hardware, software, and/or firmware. For example, the GUI generation circuitry 712 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the water conditions controller circuitry 120 of FIGS. 1-4 is illustrated in FIG. 7, one or more of the elements, processes, and/or devices illustrated in FIG. 7 may be combined, divided, re-arranged, omitted, eliminated, and/or implemented in any other way. Further, the example communications interface circuitry 702, the example user interface circuitry 704, the example mode selection circuitry 706, the example sensor data analysis circuitry 708, the example operations control circuitry 710, the example GUI generation circuitry 712, the example memory 714, and/or, more generally, the example water conditions controller circuitry 120 of FIG. 7, may be implemented by hardware alone or by hardware in combination with software and/or firmware. Thus, for example, any of the example communications interface circuitry 702, the example user interface circuitry 704, the example mode selection circuitry 706, the example sensor data analysis circuitry 708, the example operations control circuitry 710, the example GUI generation circuitry 712, the example memory 714, and/or, more generally, the example water conditions controller circuitry 120, could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine readable instructions (e.g., firmware or software). Further still, the example water conditions controller circuitry 120 of FIG. 7 may include one or more elements, processes, and/or devices in addition to, or instead of, those illustrated in FIG. 7, and/or may include more than one of any or all of the illustrated elements, processes and devices.

A flowchart representative of example machine readable instructions, which may be executed by programmable circuitry to implement and/or instantiate the water conditions controller circuitry 120 of FIG. 7 and/or representative of example operations which may be performed by programmable circuitry to implement and/or instantiate the water conditions controller circuitry 120 of FIG. 7, is shown in FIG. 8. The machine readable instructions may be one or more executable programs or portion(s) of one or more executable programs for execution by programmable circuitry such as the programmable circuitry 1312 shown in the example processor platform 1300 discussed below in connection with FIG. 13 and/or may be one or more function(s) or portion(s) of functions to be performed by the example programmable circuitry (e.g., an FPGA) discussed below in connection with FIGS. 14 and/or 15. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 8, many other methods of implementing the example water conditions controller circuitry 120 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, a CPU, a GPU, a VPU, and/or an FPGA. The programmable circuitry may include one or more CPUs, one or more GPUs, one or more VPUs, and/or one or more FPGAs located in the same package (e.g., the same integrated circuit (IC) package or in two or more separate housings), one or more CPUs, GPUs, VPUs, and/or one or more FPGAs in a single machine, multiple CPUs, GPUs, VPUs, and/or FPGAs distributed across multiple servers of a server rack, and/or multiple CPUs, GPUs, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIG. 8 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 8 is a flowchart representative of example machine readable instructions and/or example operations 800 that may be executed, instantiated, and/or performed by programmable circuitry to implement the example water conditions controller circuitry of FIG. 7 to control the flow rate and/or the temperature of water provided to the CDU 108 of the example cooling system 100 of FIG. 1. For purposes of simplicity, the flowchart of FIG. 8 is shown and described with reference to a single instance of the water conditions adjustment system 118 shown in FIGS. 1-6. However, multiple instances of the example operations 800 can be implemented in parallel for each instance of the water conditions adjustment systems 118.

The example machine-readable instructions and/or the example operations 800 of FIG. 8 begin at block 802, where the example mode selection circuitry 706 determines whether the water conditions adjustment system 118 is to operate in the open loop operation mode or the close loop operate motion. In some examples, this determination is made based on user input selecting either the open loop mode or the closed loop mode. If the system is to operate in the open loop mode, control advances to block 804 where the example operations control circuitry 710 is to cause deactivation of the pump 180. If the pump 180 is already turned off, block 804 can be skipped. Thereafter, at block 806, the example operations control circuitry 710 causes the solenoid valves 134, 172 to open. In some examples, this is accomplished by the operations control circuitry 710 stopping the transmission of a close signal, thereby enabling the normally open valves to move to the open state. In some examples, if the solenoid valves are already open, block 806 can be skipped. Thereafter, control advances to block 812.

Returning to block 802, if the system 118 is to operate in the closed loop mode, control advances to block 808 where the example operations control circuitry 710 is to cause the solenoid valves 134, 172 to close. Thereafter, at block 810, the example operations control circuitry 710 is to cause activation of the pump 180. In some examples, the operations controller circuitry 710 confirms the fifth and sixth valves 176, 178 (e.g., based on confirmation from a user received via the user interface circuitry 704) are opened before activating the pump. Thereafter, control advances to block 812.

At block 812, the example mode selection circuitry 706 determines whether to implement the valve versus flow rate control mode. In some examples, this is determined based on input from a user received via the user interface circuitry 704. If the valve versus flow rate control mode is to be implemented, control advances to block 814 where the example sensor data analysis circuitry 708 obtains (e.g., via the communications interface circuitry 702) a measured flow rate from the flowmeter 140. At block 816, the example sensor data analysis circuitry 708 compares the measured flow rate to a target flow rate (e.g., a flow rate setpoint). In some examples, this comparison is based on a PID control logic that compares the current (e.g., most recent) measured flow rate to the target flow rate, and also compares the differences between these values and the rate of change in such differences. At block 818, the example operations control circuitry 710 adjusts the opening of the flow control valve 138 based on the comparison. Thereafter, control advances to block 820. Returning to block 812, if the valve versus flow rate control mode is not to be implemented, control advances directly to block 820.

At block 820, the example mode selection circuitry 706 determines whether to implement the heater versus temperature control mode. In some examples, this is determined based on input from a user received via the user interface circuitry 704. If the heater versus temperature control mode is to be implemented, control advances to block 822 where the example sensor data analysis circuitry 708 obtains (e.g., via the communications interface circuitry 702) a measured temperature from a temperature sensor (e.g., one or more of the temperature sensors 144, 146, 152, 164, 184, 186). At block 824, the example sensor data analysis circuitry 708 compares the measured temperature to a target temperature (e.g., a temperature setpoint). In some examples, this comparison is based on a PID control logic that compares the current (e.g., most recent) measured flow rate to the target flow rate, and also compares the differences between these values and the rate of change in such differences. At block 826, the example operations control circuitry 710 controls activation of the heater based on the comparison. Thereafter, control advances to block 828. Returning to block 820, if the heater versus temperature control mode is not to be implemented, control advances directly to block 828.

At block 828, the example mode selection circuitry 706 determines whether to implement the valve versus temperature control mode. In some examples, this is determined based on input from a user received via the user interface circuitry 704. If the valve versus temperature control mode is to be implemented, control advances to block 830 where the example sensor data analysis circuitry 708 obtains (e.g., via the communications interface circuitry 702) a measured temperature from a temperature sensor. In some examples, this includes one or more of the temperature sensors 184, 186 in the cooling tank 102. At block 832, the example sensor data analysis circuitry 708 compares the measured temperature to a target temperature (e.g., a temperature setpoint). In some examples, this comparison is based on a PID control logic that compares the current (e.g., most recent) measured flow rate to the target flow rate, and also compares the differences between these values and the rate of change in such differences. At block 834, the example operations control circuitry 710 adjusts the opening of the flow control valve 138 based on the comparison. Thereafter, control advances to block 836. Returning to block 828, if the valve versus temperature control mode is not to be implemented, control advances directly to block 836.

At block 836, the example mode selection circuitry 706 determines whether to switch between operation modes. If so, control returns to block 802. Otherwise, control advances to block 838 where the operations control circuitry 710 determines whether to continue. If so, control returns to block 812. Otherwise, the example process of FIG. 8 ends.

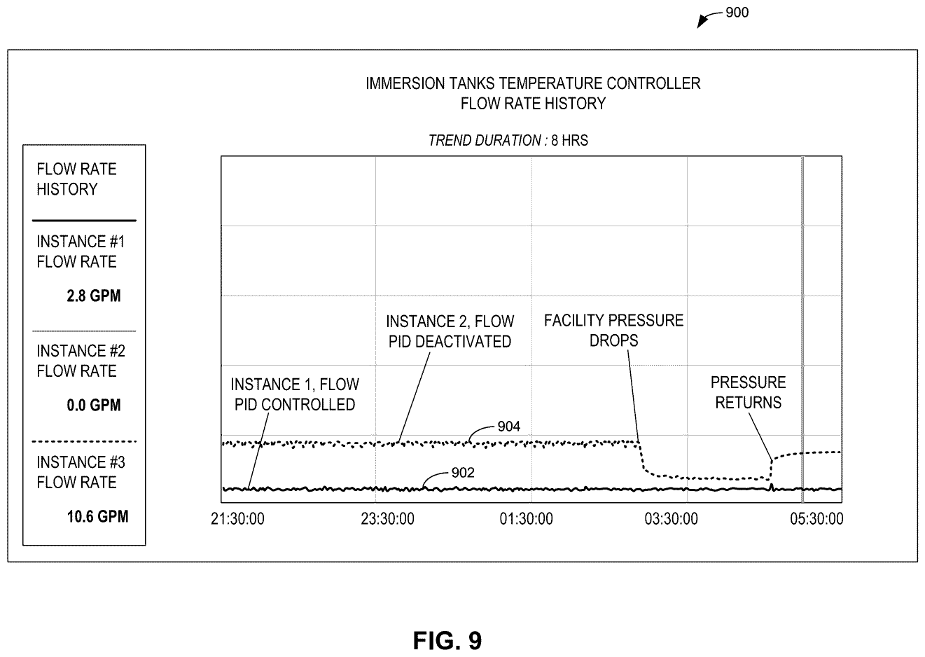

FIG. 9 illustrates an example graphical user interface (GUI) 900 that may be generated by the example GUI generation circuitry 712 of the water conditions controller circuitry 120 shown in FIG. 7. The example GUI 900 of FIG. 9 is based on real data that illustrates the benefits and advantages of teachings disclosed herein. More particularly, the example GUI 900 includes a graph showing trendlines 902, 904 representative of the measured flow rate over time for two instances of the water condition adjustment system 118 of FIGS. 1-6. As labelled in the illustrated example, the first instance of the system 118 associated with the first trendline 902 implements the control logic disclosed herein to control the flow rate of water provided to an associated CDU 108 by adjusting the opening of the flow control valve 138. By contrast, the second instance of the system 118 associated with the second trendline 904 does not implement the control logic disclosed herein. That is, the second trendline 904 represents the results of existing techniques to implement an immersion cooling system. During the period of time represented in FIG. 9, there is a sudden pressure drop in the datacenter water supply. This is easily identified in the second trendline 904 where there is a sudden and precipitous drop in the measured flow rate of water. This sudden drop in pressure can result in insufficient heat transfer within a downstream CDU affecting the cooling of electronic components in an associated immersion cooling tank. By comparison, the first trendline 902 shows no significant change in flow rate because the flow control valve 138 was adjusted in response to the pressure drop to maintain a substantially consistent flow rate at the CDU 108 for more consistent control of heat transfer with the immersion fluid 104 in an associated cooling tank 102.

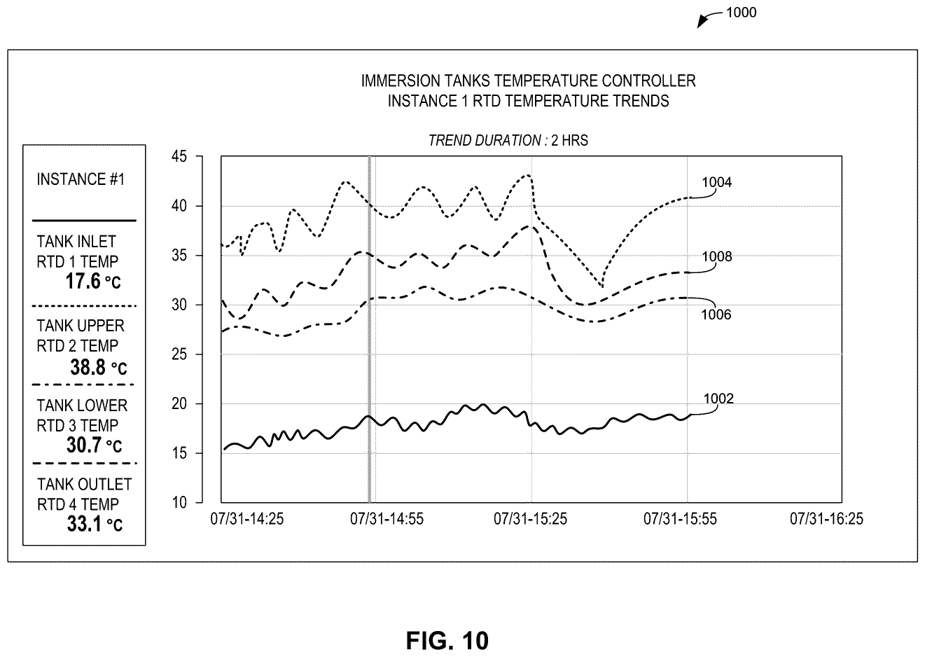

FIG. 10 illustrates another example graphical user interface (GUI) 1000 that may be generated by the example GUI generation circuitry 712 of the water conditions controller circuitry 120 shown in FIG. 7. The example GUI 1000 of FIG. 10 is based on real data associated with the implementation of a cooling system using known techniques (e.g., where there is no dynamic control of the conditions of the water being supplied to a CDU). The GUI 1000 of FIG. 10 includes a first trendline 1002 representative of the measured temperature of the water at the inlet of the CDU over time. Second and third trendlines 1004, 1006 represent the measured temperature of immersion fluid inside an immersion tank at respective upper and lower parts of the tank. A fourth trendline 1008 represents the temperature of the water at the outlet of the CDU. As shown in FIG. 10, there is considerable variability in the inlet temperature of the water that includes both small oscillations on a relatively short timescale as well as a migration of the temperature over a longer time scale. The variability of the inlet temperature results in relatively large fluctuations and corresponding migration of the temperature of the immersion fluid in the associated cooling tank.

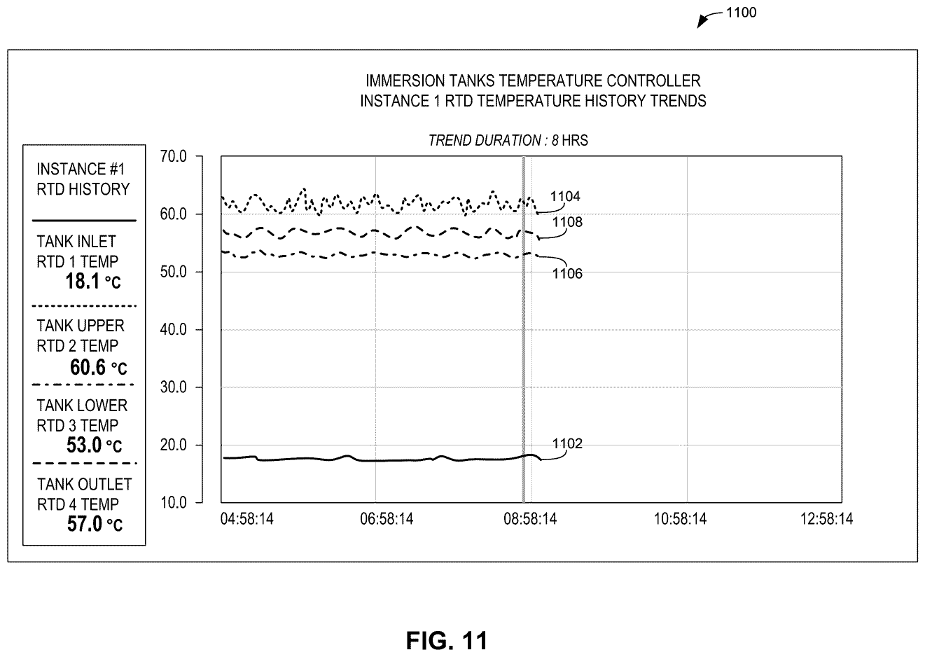

FIG. 11 illustrates another example graphical user interface (GUI) 1100 that may be generated by the example GUI generation circuitry 712 of the water conditions controller circuitry 120 shown in FIG. 7. The example GUI 1100 of FIG. 11 is similar to the GUI 1000 of FIG. 10 except that in the illustrated example of FIG. 11, the heater versus temperature control mode is implemented to control the temperature of the water being provided to the CDU 108. The GUI 1100 of FIG. 11 includes a first trendline 1102 representative of the measured temperature of the water at the inlet of the CDU over time. Second and third trendlines 1104, 1106 represent the measured temperature of immersion fluid inside an immersion tank at the upper and lower parts of the tank, respectively. A fourth trendline 1108 represents the temperature of the water at the outlet of the CDU. As shown in FIG. 11, there is significantly less variation in the inlet temperature of the water (represented by the first trendline 1102) and the temperature is maintained at a substantially consistent temperature (e.g., there is little to no migration of the inlet temperature over time) as compared to the first trendline 1002 in FIG. 10. More particularly, the oscillations in the inlet water temperature shown in FIG. 10 (that is not temperature controlled) have an amplitude of approximately +/−1.5°C, whereas variations in the inlet water temperature in FIG. 11 (that is temperature controlled in accordance with teachings disclosed herein) have an amplitude of approximately +/−0.2°C.

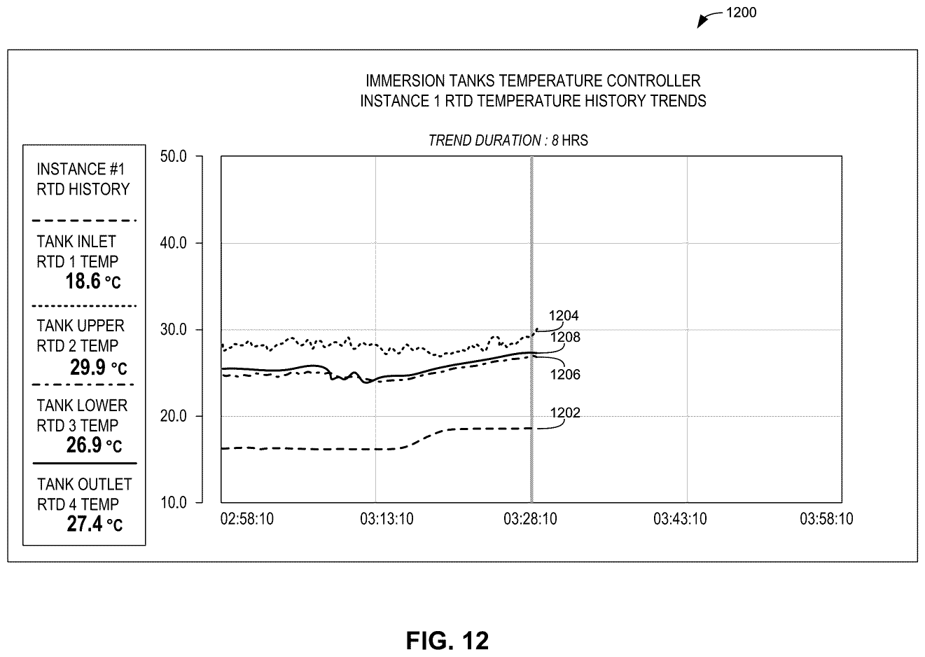

FIG. 12 illustrates another example graphical user interface (GUI) 1200 that may be generated by the example GUI generation circuitry 712 of the water conditions controller circuitry 120 shown in FIG. 7. The example GUI 1200 of FIG. 12 is similar to the GUI 1100 of FIG. 11 in that the heater versus temperature control mode is implemented to control the temperature of processed water being provided to the CDU 108. The GUI 1200 of FIG. 12 includes a first trendline 1202 representative of the measured temperature of the water at the inlet of the CDU over time. Second and third trendlines 1204, 1206 represent the measured temperature of immersion fluid inside an immersion tank at the upper and lower parts of the tank, respectively. A fourth trendline 1208 represents the temperature of the water at the outlet of the CDU. In the example of FIG. 12, the temperature setpoint for the inlet temperature is increased by 1.5° C. As represented by the first trendline 1202, the system is able to relatively quickly (e.g., in a matter of minutes) and smoothly increase the temperature from the initial setpoint to the new setpoint without difficulty.

FIG. 13 is a block diagram of an example programmable circuitry platform 1300 structured to execute and/or instantiate the example machine-readable instructions and/or the example operations of FIG. 8 to implement the water conditions controller circuitry 120 of FIG. 7. The programmable circuitry platform 1300 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, or any other type of computing and/or electronic device.

The programmable circuitry platform 1300 of the illustrated example includes programmable circuitry 1312. The programmable circuitry 1312 of the illustrated example is hardware. For example, the programmable circuitry 1312 can be implemented by one or more integrated circuits, logic circuits, FPGAs, microprocessors, CPUs, GPUs, VPUs, DSPs, and/or microcontrollers from any desired family or manufacturer. The programmable circuitry 1312 may be implemented by one or more semiconductor based (e.g., silicon based) devices. In this example, the programmable circuitry 1312 implements the example communications interface circuitry 702, the example user interface circuitry 704, the example mode selection circuitry 706, the example sensor data analysis circuitry 708, the example operations control circuitry 710, and the example GUI generation circuitry 712.

The programmable circuitry 1312 of the illustrated example includes a local memory 1313 (e.g., a cache, registers, etc.). The programmable circuitry 1312 of the illustrated example is in communication with main memory 1314, 1316, which includes a volatile memory 1314 and a non-volatile memory 1316, by a bus 1318. The volatile memory 1314 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1316 may be implemented by flash memory and/or any other desired type of memory device. Access to the main memory 1314, 1316 of the illustrated example is controlled by a memory controller 1317. In some examples, the memory controller 1317 may be implemented by one or more integrated circuits, logic circuits, microcontrollers from any desired family or manufacturer, or any other type of circuitry to manage the flow of data going to and from the main memory 1314, 1316.

The programmable circuitry platform 1300 of the illustrated example also includes interface circuitry 1320. The interface circuitry 1320 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1322 are connected to the interface circuitry 1320. The input device(s) 1322 permit(s) a user (e.g., a human user, a machine user, etc.) to enter data and/or commands into the programmable circuitry 1312. The input device(s) 1322 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1324 are also connected to the interface circuitry 1320 of the illustrated example. The output device(s) 1324 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1320 of the illustrated example, thus, typically includes a graphics driver card, a graphics driver chip, and/or graphics processor circuitry such as a GPU.

The interface circuitry 1320 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1326. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1300 of the illustrated example also includes one or more mass storage discs or devices 1328 to store firmware, software, and/or data. Examples of such mass storage discs or devices 1328 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1332, which may be implemented by the machine readable instructions of FIG. 8, may be stored in the mass storage device 1328, in the volatile memory 1314, in the non-volatile memory 1316, and/or on at least one non-transitory computer readable storage medium such as a CD or DVD which may be removable.

FIG. 14 is a block diagram of an example implementation of the programmable circuitry 1312 of FIG. 13. In this example, the programmable circuitry 1312 of FIG. 13 is implemented by a microprocessor 1400. For example, the microprocessor 1400 may be a general-purpose microprocessor (e.g., general-purpose microprocessor circuitry). The microprocessor 1400 executes some or all of the machine-readable instructions of the flowchart of FIG. 8 to effectively instantiate the circuitry of FIG. 7 as logic circuits to perform operations corresponding to those machine readable instructions. In some such examples, the circuitry of FIG. 7 is instantiated by the hardware circuits of the microprocessor 1400 in combination with the machine-readable instructions. For example, the microprocessor 1400 may be implemented by multi-core hardware circuitry such as a CPU, a DSP, a GPU, an XPU, etc. Although it may include any number of example cores 1402 (e.g., 1 core), the microprocessor 1400 of this example is a multi-core semiconductor device including N cores. The cores 1402 of the microprocessor 1400 may operate independently or may cooperate to execute machine readable instructions. For example, machine code corresponding to a firmware program, an embedded software program, or a software program may be executed by one of the cores 1402 or may be executed by multiple ones of the cores 1402 at the same or different times. In some examples, the machine code corresponding to the firmware program, the embedded software program, or the software program is split into threads and executed in parallel by two or more of the cores 1402. The software program may correspond to a portion or all of the machine readable instructions and/or operations represented by the flowchart of FIG. 8.

The cores 1402 may communicate by a first example bus 1404. In some examples, the first bus 1404 may be implemented by a communication bus to effectuate communication associated with one(s) of the cores 1402. For example, the first bus 1404 may be implemented by at least one of an Inter-Integrated Circuit (I2C) bus, a Serial Peripheral Interface (SPI) bus, a PCI bus, or a PCIe bus. Additionally or alternatively, the first bus 1404 may be implemented by any other type of computing or electrical bus. The cores 1402 may obtain data, instructions, and/or signals from one or more external devices by example interface circuitry 1406. The cores 1402 may output data, instructions, and/or signals to the one or more external devices by the interface circuitry 1406. Although the cores 1402 of this example include example local memory 1420 (e.g., Level 1 (L1) cache that may be split into an L1 data cache and an L1 instruction cache), the microprocessor 1400 also includes example shared memory 1410 that may be shared by the cores (e.g., Level 2 (L2 cache)) for high-speed access to data and/or instructions. Data and/or instructions may be transferred (e.g., shared) by writing to and/or reading from the shared memory 1410. The local memory 1420 of each of the cores 1402 and the shared memory 1410 may be part of a hierarchy of storage devices including multiple levels of cache memory and the main memory (e.g., the main memory 1314, 1316 of FIG. 13). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1402 may be referred to as a CPU, DSP, GPU, etc., or any other type of hardware circuitry. Each core 1402 includes control unit circuitry 1414, arithmetic and logic (AL) circuitry (sometimes referred to as an ALU) 1416, a plurality of registers 1418, the local memory 1420, and a second example bus 1422. Other structures may be present. For example, each core 1402 may include vector unit circuitry, single instruction multiple data (SIMD) unit circuitry, load/store unit (LSU) circuitry, branch/jump unit circuitry, floating-point unit (FPU) circuitry, etc. The control unit circuitry 1414 includes semiconductor-based circuits structured to control (e.g., coordinate) data movement within the corresponding core 1402. The AL circuitry 1416 includes semiconductor-based circuits structured to perform one or more mathematic and/or logic operations on the data within the corresponding core 1402. The AL circuitry 1416 of some examples performs integer based operations. In other examples, the AL circuitry 1416 also performs floating-point operations. In yet other examples, the AL circuitry 1416 may include first AL circuitry that performs integer-based operations and second AL circuitry that performs floating-point operations. In some examples, the AL circuitry 1416 may be referred to as an Arithmetic Logic Unit (ALU).

The registers 1418 are semiconductor-based structures to store data and/or instructions such as results of one or more of the operations performed by the AL circuitry 1416 of the corresponding core 1402. For example, the registers 1418 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1418 may be arranged in a bank as shown in FIG. 14. Alternatively, the registers 1418 may be organized in any other arrangement, format, or structure, such as by being distributed throughout the core 1402 to shorten access time. The second bus 1422 may be implemented by at least one of an I2C bus, a SPI bus, a PCI bus, or a PCIe bus.

Each core 1402 and/or, more generally, the microprocessor 1400 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1400 is a semiconductor device fabricated to include many transistors interconnected to implement the structures described above in one or more integrated circuits (ICs) contained in one or more packages.

The microprocessor 1400 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1400, in the same chip package as the microprocessor 1400 and/or in one or more separate packages from the microprocessor 1400.

FIG. 15 is a block diagram of another example implementation of the programmable circuitry 1312 of FIG. 13. In this example, the programmable circuitry 1312 is implemented by FPGA circuitry 1500. For example, the FPGA circuitry 1500 may be implemented by an FPGA. The FPGA circuitry 1500 can be used, for example, to perform operations that could otherwise be performed by the example microprocessor 1400 of FIG. 14 executing corresponding machine readable instructions. However, once configured, the FPGA circuitry 1500 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1400 of FIG. 14 described above (which is a general purpose device that may be programmed to execute some or all of the machine readable instructions represented by the flowchart(s) of FIG. 8 but whose interconnections and logic circuitry are fixed once fabricated), the FPGA circuitry 1500 of the example of FIG. 15 includes interconnections and logic circuitry that may be configured, structured, programmed, and/or interconnected in different ways after fabrication to instantiate, for example, some or all of the operations/functions corresponding to the machine readable instructions represented by the flowchart(s) of FIG. 8. In particular, the FPGA circuitry 1500 may be thought of as an array of logic gates, interconnections, and switches. The switches can be programmed to change how the logic gates are interconnected by the interconnections, effectively forming one or more dedicated logic circuits (unless and until the FPGA circuitry 1500 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIG. 8. As such, the FPGA circuitry 1500 may be configured and/or structured to effectively instantiate some or all of the operations/functions corresponding to the machine readable instructions of the flowchart(s) of FIG. 8 as dedicated logic circuits to perform the operations/functions corresponding to those software instructions in a dedicated manner analogous to an ASIC. Therefore, the FPGA circuitry 1500 may perform the operations/functions corresponding to the some or all of the machine readable instructions of FIG. 8 faster than the general-purpose microprocessor can execute the same.

In the example of FIG. 15, the FPGA circuitry 1500 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1500 of FIG. 15 may access and/or load the binary file to cause the FPGA circuitry 1500 of FIG. 15 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1500 of FIG. 15 to cause configuration and/or structuring of the FPGA circuitry 1500 of FIG. 15, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1500 of FIG. 15 may access and/or load the binary file to cause the FPGA circuitry 1500 of FIG. 15 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1500 of FIG. 15 to cause configuration and/or structuring of the FPGA circuitry 1500 of FIG. 15, or portion(s) thereof.

The FPGA circuitry 1500 of FIG. 15, includes example input/output (I/O) circuitry 1502 to obtain and/or output data to/from example configuration circuitry 1504 and/or external hardware 1506. For example, the configuration circuitry 1504 may be implemented by interface circuitry that may obtain a binary file, which may be implemented by a bit stream, data, and/or machine-readable instructions, to configure the FPGA circuitry 1500, or portion(s) thereof. In some such examples, the configuration circuitry 1504 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1506 may be implemented by external hardware circuitry. For example, the external hardware 1506 may be implemented by the microprocessor 1400 of FIG. 14.

The FPGA circuitry 1500 also includes an array of example logic gate circuitry 1508, a plurality of example configurable interconnections 1510, and example storage circuitry 1512. The logic gate circuitry 1508 and the configurable interconnections 1510 are configurable to instantiate one or more operations/functions that may correspond to at least some of the machine readable instructions of FIG. 8 and/or other desired operations. The logic gate circuitry 1508 shown in FIG. 15 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1508 to enable configuration of the electrical structures and/or the logic gates to form circuits to perform desired operations/functions. The logic gate circuitry 1508 may include other electrical structures such as look-up tables (LUTs), registers (e.g., flip-flops or latches), multiplexers, etc.

The configurable interconnections 1510 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1508 to program desired logic circuits.

The storage circuitry 1512 of the illustrated example is structured to store result(s) of the one or more of the operations performed by corresponding logic gates. The storage circuitry 1512 may be implemented by registers or the like. In the illustrated example, the storage circuitry 1512 is distributed amongst the logic gate circuitry 1508 to facilitate access and increase execution speed.

The example FPGA circuitry 1500 of FIG. 15 also includes example dedicated operations circuitry 1514. In this example, the dedicated operations circuitry 1514 includes special purpose circuitry 1516 that may be invoked to implement commonly used functions to avoid the need to program those functions in the field. Examples of such special purpose circuitry 1516 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1500 may also include example general purpose programmable circuitry 1518 such as an example CPU 1520 and/or an example DSP 1522. Other general purpose programmable circuitry 1518 may additionally or alternatively be present such as a GPU, an XPU, etc., that can be programmed to perform other operations.

Although FIGS. 14 and 15 illustrate two example implementations of the programmable circuitry 1312 of FIG. 13, many other approaches are contemplated. For example, FPGA circuitry may include an on-board CPU, such as one or more of the example CPU 1520 of FIG. 14. Therefore, the programmable circuitry 1312 of FIG. 13 may additionally be implemented by combining at least the example microprocessor 1400 of FIG. 14 and the example FPGA circuitry 1500 of FIG. 15. In some such hybrid examples, one or more cores 1402 of FIG. 14 may execute a first portion of the machine readable instructions represented by the flowchart(s) of FIG. 8 to perform first operation(s)/function(s), the FPGA circuitry 1500 of FIG. 15 may be configured and/or structured to perform second operation(s)/function(s) corresponding to a second portion of the machine readable instructions represented by the flowcharts of FIG. 8, and/or an ASIC may be configured and/or structured to perform third operation(s)/function(s) corresponding to a third portion of the machine readable instructions represented by the flowchart of FIG. 8.

It should be understood that some or all of the circuitry of FIG. 7 may, thus, be instantiated at the same or different times. For example, same and/or different portion(s) of the microprocessor 1400 of FIG. 14 may be programmed to execute portion(s) of machine-readable instructions at the same and/or different times. In some examples, same and/or different portion(s) of the FPGA circuitry 1500 of FIG. 15 may be configured and/or structured to perform operations/functions corresponding to portion(s) of machine-readable instructions at the same and/or different times.

In some examples, some or all of the circuitry of FIG. 7 may be instantiated, for example, in one or more threads executing concurrently and/or in series. For example, the microprocessor 1400 of FIG. 14 may execute machine readable instructions in one or more threads executing concurrently and/or in series. In some examples, the FPGA circuitry 1500 of FIG. 15 may be configured and/or structured to carry out operations/functions concurrently and/or in series. Moreover, in some examples, some or all of the circuitry of FIG. 7 may be implemented within one or more virtual machines and/or containers executing on the microprocessor 1400 of FIG. 14.

In some examples, the programmable circuitry 1312 of FIG. 13 may be in one or more packages. For example, the microprocessor 1400 of FIG. 14 and/or the FPGA circuitry 1500 of FIG. 15 may be in one or more packages. In some examples, an XPU may be implemented by the programmable circuitry 1312 of FIG. 13, which may be in one or more packages. For example, the XPU may include a CPU (e.g., the microprocessor 1400 of FIG. 14, the CPU 1520 of FIG. 15, etc.) in one package, a DSP (e.g., the DSP 1522 of FIG. 15) in another package, a GPU in yet another package, and an FPGA (e.g., the FPGA circuitry 1500 of FIG. 15) in still yet another package.

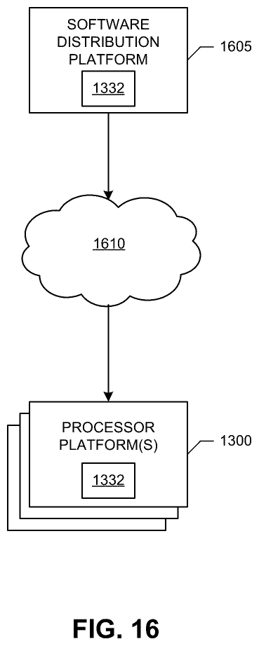

A block diagram illustrating an example software distribution platform 1605 to distribute software such as the example machine readable instructions 1332 of FIG. 13 to other hardware devices (e.g., hardware devices owned and/or operated by third parties from the owner and/or operator of the software distribution platform) is illustrated in FIG. 16. The example software distribution platform 1605 may be implemented by any computer server, data facility, cloud service, etc., capable of storing and transmitting software to other computing devices. The third parties may be customers of the entity owning and/or operating the software distribution platform 1605. For example, the entity that owns and/or operates the software distribution platform 1605 may be a developer, a seller, and/or a licensor of software such as the example machine readable instructions 1332 of FIG. 13. The third parties may be consumers, users, retailers, OEMs, etc., who purchase and/or license the software for use and/or re-sale and/or sub-licensing. In the illustrated example, the software distribution platform 1605 includes one or more servers and one or more storage devices. The storage devices store the machine readable instructions 1332, which may correspond to the example machine readable instructions of FIG. 8, as described above. The one or more servers of the example software distribution platform 1605 are in communication with an example network 1610, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1332 from the software distribution platform 1605. For example, the software, which may correspond to the example machine readable instructions of FIG. 8, may be downloaded to the example programmable circuitry platform 1300, which is to execute the machine readable instructions 1332 to implement the water conditions controller circuitry 120. In some examples, one or more servers of the software distribution platform 1605 periodically offer, transmit, and/or force updates to the software (e.g., the example machine readable instructions 1332 of FIG. 13) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third. ” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time”refers to real time +2 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve control of the temperature of an immersion fluid within an immersion cooling tank for enhanced (e.g., more consistent and reliable) cooling of electronic components (e.g., servers) within the cooling tank. Examples disclosed herein achieve these advantages by controlling at least one of the flow rate or the temperature of processed water provided from a datacenter water processing facility and directed towards a CDU associated with the cooling tank to draw heat away from the immersion fluid. More particularly, in some examples, a flow control valve is provided upstream of the inlet of the CDU to dynamically adjust the flow rate of the water in response to at least one of a measured value of the flow rate (e.g., via a flowmeter) or a measured value of a temperature (e.g., via a temperature sensor). Additionally or alternatively, in some examples, a heater is provided upstream of the inlet of the CDU to dynamically adjust the temperature (e.g., to heat) the water before it enters the CDU. Further, in some examples, the system can be closed off to define a closed loop system with a fixed volume of the water that is pumped from the outlet side of the CDU back into the inlet side of the CDU while being heated by the heater to increase the temperature of the immersion fluid within the tank when such is desired (e.g., when the electronic components are not yet powered and the immersion fluid is to be pre-heated).

Further examples and combinations thereof include the following:

Example 1 includes an apparatus comprising a flow control valve to selectively adjust a flow rate of water to be provided to a coolant distribution unit (CDU) associated with an immersion cooling tank, the cooling tank to contain an electronic component immersed in an immersion fluid, the immersion fluid different from the water, the water from a source external to the CDU and external to the immersion cooling tank, and at least one programmable circuit to control operation of the flow control valve.

Example 2 includes the apparatus of example 1, including a flowmeter to measure the flow rate of the water between the flow control valve and the CDU, one or more of the at least one programmable circuit to control the flow control valve based on feedback from the flowmeter.

Example 3 includes the apparatus of any one or more of examples 1-2, including a temperature sensor to measure a temperature of the immersion fluid in the immersion cooling tank, one or more of the at least one programmable circuit to control the flow control valve based on feedback from the temperature sensor.

Example 4 includes the apparatus of any one or more of examples 1-3, including a heater to selectively heat the water before being provided to the CDU.

Example 5 includes the apparatus of example 4, including a temperature sensor to measure a temperature of at least one of the water or the immersion fluid in the immersion cooling tank, one or more of the at least one programmable circuit to control the heater based on feedback from the temperature sensor.

Example 6 includes the apparatus of any one or more of examples 4-5, including an inlet pipeline to direct the water to an inlet of the CDU, the flow control valve to be upstream of the heater along the inlet pipeline.

Example 7 includes the apparatus of any one or more of examples 4-6, including a bypass pipeline to enable the water to bypass the heater.

Example 8 includes the apparatus of any one or more of examples 1-7, including an inlet pipeline to direct the water from the source to an inlet of the CDU, an outlet pipeline to direct the water from an outlet of the CDU back to the source, and a closed loop pipeline to fluidly couple the outlet pipeline with the inlet pipeline independent of the source and independent of the CDU.

Example 9 includes the apparatus of example 8, including a first solenoid valve in the inlet pipeline to be upstream of a junction between the closed loop pipeline and inlet pipeline, and a second solenoid valve in the outlet pipeline to be downstream of a junction between the closed loop pipeline and outlet pipeline, the first and second solenoid valves to be open in a default state, the first and second solenoid valves to be closed when the closed loop pipeline is opened.

Example 10 includes the apparatus of any one or more of examples 8-9, including a check valve in the closed loop pipeline to prevent the water from flowing from the inlet pipeline to the outlet pipeline through the closed loop pipeline.

Example 11 includes the apparatus of any one or more of examples 8-10, including a pump in the closed loop pipeline to pump the water from the outlet pipeline to the inlet pipeline.

Example 12 includes the apparatus of any one or more of examples 1-11, wherein the flow control valve is a first flow control valve, the CDU is a first CDU, and the immersion cooling tank is a first immersion cooling tank, the apparatus including a second flow control valve to selectively adjust a flow rate of the water to be provided to a second CDU associated with a second immersion cooling tank, one or more of the at least one programmable circuit to control operation of the second flow control valve.

Example 13 includes the apparatus of example 12, including a distribution manifold to fluidly couple the source to both the first and second flow control valves.

Example 14 includes the apparatus of example 13, wherein there are no flow balancing components in the distribution manifold.

Example 15 includes the apparatus of any one or more of examples 1-14, including a controller housing to contain the at least one programmable circuit, and a frame to support the flow control valve and the controller housing.

Example 16 includes the apparatus of example 15, including a display carried by the controller housing, the at least one programmable circuit to cause a graphical user interface to be presented via the display.

Example 17 includes an apparatus comprising means for adjusting a flow rate of water to be provided to a coolant distribution unit (CDU) associated with an immersion cooling tank, the immersion cooling tank to contain an electronic component immersed in an immersion fluid, the immersion fluid different from the water, means for heating the water to be provided to the CDU, and means for controlling operation of at least one of the means for adjusting or the means for heating.

Example 18 includes the apparatus of example 17, including means for measuring the flow rate of the water, the means for controlling to control the means for adjusting based on feedback from the means for measuring the flow rate.

Example 19 includes the apparatus of any one or more of examples 17-18, including means for measuring a temperature of the water, the means for controlling to control the means for adjusting based on feedback from the means for measuring the temperature.

Example 20 includes the apparatus of any one or more of examples 17-19, including means for measuring a temperature of the water, the means for controlling to control the means for heating based on feedback from the means for measuring the temperature.

Example 21 includes the apparatus of any one or more of examples 17-20, wherein the means for adjusting is upstream of the means for heating relative to a flow direction of the water.

Example 22 includes the apparatus of any one or more of examples 17-21, including means for bypassing the means for heating.

Example 23 includes the apparatus of any one or more of examples 17-22, including first means for closing off the water from a water processing facility on an upstream side of the CDU, second means for closing off the water from the water processing facility on a downstream side of the CDU, and means for fluidly coupling the downstream side of the CDU to the upstream side of the CDU at a location between the first means for closing off the water and the means for adjusting.

Example 24 includes the apparatus of example 23, including means for pumping the water through a closed loop enabled by the first and second means for closing off the water and the means for fluidly coupling.

Example 25 includes an apparatus comprising memory, machine readable instructions, and at least one programmable circuit to execute the machine readable instructions to obtain a measured flow rate of water supplied to a coolant distribution unit (CDU) associated with an immersion cooling tank, the water to be thermally coupled to an immersion fluid in the immersion cooling tank via a heat exchanger, and control an opening of a flow control valve based on a comparison of the measured flow rate to a target flow rate, adjustment to the opening of the flow control valve to adjust the flow rate of the water supplied to the CDU.

Example 26 includes the apparatus of example 25, wherein one or more of the at least one programmable circuit is to obtain a measured temperature, and control activation of a heater based on a comparison of the measured temperature to a target temperature, the heater to heat the water before being provided to the CDU.

Example 27 includes the apparatus of example 26, wherein the measured temperature includes a temperature of the immersion fluid inside the immersion cooling tank, the immersion fluid different from the water.

Example 28 includes the apparatus of any one or more of examples 26-27, wherein the measured temperature includes a temperature of the water.

Example 29 includes the apparatus of example 28, wherein the measured temperature is taken after the water passes the heater and before the water enters the CDU.

Example 30 includes the apparatus of any one or more of examples 26-29, wherein one or more of the at least one programmable circuit is to control the activation of the heater by providing power to the heater via pulse width modulation.

Example 31 includes the apparatus of any one or more of examples 26-30, wherein one or more of the at least one programmable circuit is to control the opening of the flow control valve based on a proportional-integral-derivative feedback loop.

Example 32 includes the apparatus of any one or more of examples 25-31, wherein one or more of the at least one programmable circuit is to obtain a measured temperature, and control the opening of the flow control valve based on a comparison of the measured temperature to a target temperature.

Example 33 includes the apparatus of example 32, wherein the measured temperature includes a temperature of the immersion fluid inside the immersion cooling tank, the immersion fluid different from the water.

Example 34 includes the apparatus of any one or more of examples 25-33, wherein one or more of the at least one programmable circuit is to cause a first solenoid valve to close, the first solenoid valve to be upstream of the flow control valve along a first pipeline that directs the water toward an inlet of the CDU, cause a second solenoid valve to close, the second solenoid valve to be in a second pipeline that directs the water away from an outlet of the CDU, and cause activation of a pump to force water from the second pipeline to the first pipeline via a third pipeline extending therebetween, the third pipeline to connect to the first pipeline at a point between the first solenoid valve and the flow control valve, the third pipeline to connect to the second pipeline at a location that is upstream of the second solenoid valve.

Example 35 includes a non-transitory machine readable storage medium comprising instructions to cause at least one programmable circuit to at least obtain a measured flow rate of water supplied to a coolant distribution unit (CDU) associated with an immersion cooling tank, the water to be thermally coupled to an immersion fluid in the immersion cooling tank via a heat exchanger, and control an opening of a flow control valve based on a comparison of the measured flow rate to a target flow rate, adjustment to the opening of the flow control valve to adjust the flow rate of the water supplied to the CDU.

Example 36 includes the machine readable storage medium of example 35, wherein the instructions are to cause one or more of the at least one programmable circuit to obtain a measured temperature, and control activation of a heater based on a comparison of the measured temperature to a target temperature, the heater to heat the water before being provided to the CDU.

Example 37 includes the machine readable storage medium of example 36, wherein the measured temperature includes a temperature of the immersion fluid inside the immersion cooling tank, the immersion fluid different from the water.

Example 38 includes the apparatus of any one or more of examples 36-37, wherein the measured temperature includes a temperature of the water.

Example 39 includes the machine readable storage medium of example 38, wherein the measured temperature is taken after the water passes the heater and before the water enters the CDU.

Example 40 includes the apparatus of any one or more of examples 36-39, wherein the instructions are to cause one or more of the at least one programmable circuit to control the activation of the heater by providing power to the heater via pulse width modulation.

Example 41 includes the apparatus of any one or more of examples 36-40, wherein the instructions are to cause one or more of the at least one programmable circuit to control the opening of the flow control valve based on a proportional-integral-derivative feedback loop.

Example 42 includes the apparatus of any one or more of examples 35-41, wherein the instructions are to cause one or more of the at least one programmable circuit to obtain a measured temperature, and control the opening of the flow control valve based on a comparison of the measured temperature to a target temperature.

Example 43 includes the machine readable storage medium of example 42, wherein the measured temperature includes a temperature of the immersion fluid inside the immersion cooling tank, the immersion fluid different from the water.

Example 44 includes the apparatus of any one or more of examples 35-43, wherein the instructions are to cause one or more of the at least one programmable circuit to cause a first solenoid valve to close, the first solenoid valve to be upstream of the flow control valve along a first pipeline that directs the water toward an inlet of the CDU, cause a second solenoid valve to close, the second solenoid valve to be in a second pipeline that directs the water away from an outlet of the CDU, and cause activation of a pump to force water from the second pipeline to the first pipeline via a third pipeline extending therebetween, the third pipeline to connect to the first pipeline at a point between the first solenoid valve and the flow control valve, the third pipeline to connect to the second pipeline at a location that is upstream of the second solenoid valve.

Example 45 includes a method comprising obtaining a measured flow rate of water supplied to a coolant distribution unit (CDU) associated with an immersion cooling tank, the water to be thermally coupled to an immersion fluid in the immersion cooling tank via a heat exchanger, and controlling, by executing instructions with at least one programmable circuit, an opening of a flow control valve based on a comparison of the measured flow rate to a target flow rate, adjustment to the opening of the flow control valve to adjust the flow rate of the water supplied to the CDU.

Example 46 includes the method of example 45, including obtaining a measured temperature, and controlling activation of a heater based on a comparison of the measured temperature to a target temperature, the heater to heat the water before being provided to the CDU.

Example 47 includes the method of example 46, wherein the measured temperature includes a temperature of the immersion fluid inside the immersion cooling tank, the immersion fluid different from the water.

Example 48 includes the method of any one or more of examples 46-47, wherein the measured temperature includes a temperature of the water.

Example 49 includes the method of example 48, wherein the measured temperature is taken after the water passes the heater and before the water enters the CDU.

Example 50 includes the method of any one or more of examples 46-49, wherein the controlling of the activation of the heater includes providing power to the heater via pulse width modulation.

Example 51 includes the method of any one or more of examples 46-50, wherein the controlling of the opening of the flow control valve is based on a proportional-integral-derivative feedback loop.

Example 52 includes the method of any one or more of examples 45-51, including obtaining a measured temperature, and controlling the opening of the flow control valve based on a comparison of the measured temperature to a target temperature.

Example 53 includes the method of example 52, wherein the measured temperature includes a temperature of the immersion fluid inside the immersion cooling tank, the immersion fluid different from the water.

Example 54 includes the method of any one or more of examples 45-53, including causing a first solenoid valve to close, the first solenoid valve to be upstream of the flow control valve along a first pipeline that directs the water toward an inlet of the CDU, causing a second solenoid valve to close, the second solenoid valve in a second pipeline that directs the water away from an outlet of the CDU, and causing activation of a pump to force water from the second pipeline to the first pipeline via a third pipeline extending therebetween, the third pipeline to connect to the first pipeline at a point between the first solenoid valve and the flow control valve, the third pipeline to connect to the second pipeline at a location that is upstream of the second solenoid valve.

Example 55 includes an apparatus comprising means to perform a method as claimed in any one or more of examples 45-54.

Example 56 includes machine-readable storage including machine-readable instructions, when executed, to implement a method or realize an apparatus as claimed in any one or more of examples 45-55

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
a flow control valve to selectively adjust a flow rate of water to be provided to a coolant distribution unit (CDU) associated with an immersion cooling tank, the cooling tank to contain an electronic component immersed in an immersion fluid, the immersion fluid different from the water, the water from a source external to the CDU and external to the immersion cooling tank; and
at least one programmable circuit to control operation of the flow control valve.

2. The apparatus of claim 1, including a flowmeter to measure the flow rate of the water between the flow control valve and the CDU, one or more of the at least one programmable circuit to control the flow control valve based on feedback from the flowmeter.

3. The apparatus of claim 1, including a temperature sensor to measure a temperature of the immersion fluid in the immersion cooling tank, one or more of the at least one programmable circuit to control the flow control valve based on feedback from the temperature sensor.

4. The apparatus of claim 1, including a heater to selectively heat the water before being provided to the CDU.

5. The apparatus of claim 4, including a temperature sensor to measure a temperature of at least one of the water or the immersion fluid in the immersion cooling tank, one or more of the at least one programmable circuit to control the heater based on feedback from the temperature sensor.

6. The apparatus of claim 4, including an inlet pipeline to direct the water to an inlet of the CDU, the flow control valve to be upstream of the heater along the inlet pipeline.

7. (canceled)

8. The apparatus of claim 1, including:
an inlet pipeline to direct the water from the source to an inlet of the CDU;
an outlet pipeline to direct the water from an outlet of the CDU back to the source; and
a closed loop pipeline to fluidly couple the outlet pipeline with the inlet pipeline independent of the source and independent of the CDU.

9. The apparatus of claim 8, including:
a first solenoid valve in the inlet pipeline to be upstream of a junction between the closed loop pipeline and inlet pipeline; and
a second solenoid valve in the outlet pipeline to be downstream of a junction between the closed loop pipeline and outlet pipeline, the first and second solenoid valves to be open in a default state, the first and second solenoid valves to be closed when the closed loop pipeline is opened.

10. (canceled)

11. The apparatus of claim 8, including a pump in the closed loop pipeline to pump the water from the outlet pipeline to the inlet pipeline.

12. The apparatus of claim 1, wherein the flow control valve is a first flow control valve, the CDU is a first CDU, and the immersion cooling tank is a first immersion cooling tank, the apparatus including a second flow control valve to selectively adjust a flow rate of the water to be provided to a second CDU associated with a second immersion cooling tank, one or more of the at least one programmable circuit to control operation of the second flow control valve.

13. (canceled)

14. (canceled)

15. The apparatus of claim 1, including:
a controller housing to contain the at least one programmable circuit; and
a frame to support the flow control valve and the controller housing.

16. The apparatus of claim 15, including a display carried by the controller housing, the at least one programmable circuit to cause a graphical user interface to be presented via the display.

17. An apparatus comprising:
means for adjusting a flow rate of water to be provided to a coolant distribution unit (CDU) associated with an immersion cooling tank, the immersion cooling tank to contain an electronic component immersed in an immersion fluid, the immersion fluid different from the water;
means for heating the water to be provided to the CDU; and
means for controlling operation of at least one of the means for adjusting or the means for heating.

18. The apparatus of claim 17, including means for measuring the flow rate of the water, the means for controlling to control the means for adjusting based on feedback from the means for measuring the flow rate.

19. The apparatus of claim 17, including means for measuring a temperature of the water, the means for controlling to control the means for adjusting based on feedback from the means for measuring the temperature.

20. (canceled)

21. (canceled)

22. The apparatus of claim 17, including means for bypassing the means for heating.

23. The apparatus of claim 17, including:
first means for closing off the water from a water processing facility on an upstream side of the CDU;
second means for closing off the water from the water processing facility on a downstream side of the CDU; and
means for fluidly coupling the downstream side of the CDU to the upstream side of the CDU at a location between the first means for closing off the water and the means for adjusting.

24. (canceled)

25. An apparatus comprising:
memory;
machine readable instructions; and
at least one programmable circuit to execute the machine readable instructions to:
obtain a measured flow rate of water supplied to a coolant distribution unit (CDU) associated with an immersion cooling tank, the water to be thermally coupled to an immersion fluid in the immersion cooling tank via a heat exchanger; and
control an opening of a flow control valve based on a comparison of the measured flow rate to a target flow rate, adjustment to the opening of the flow control valve to adjust the flow rate of the water supplied to the CDU.

26. The apparatus of claim 25, wherein one or more of the at least one programmable circuit is to:
obtain a measured temperature; and
control activation of a heater based on a comparison of the measured temperature to a target temperature, the heater to heat the water before being provided to the CDU.

27-31. (canceled)

32. The apparatus of claim 25, wherein one or more of the at least one programmable circuit is to:
obtain a measured temperature; and
control the opening of the flow control valve based on a comparison of the measured temperature to a target temperature.

33-54. (canceled)
